(19) United States
(12) Patent Application Publication
(10) Pub. No.: US 2026/0255465 A1
(43) Pub. Date: Aug. 27, 2026

(54) DEBRIS TRAP UNIT AND LIGHT SOURCE APPARATUS

(71) Applicant: USHIO DENKI KABUSHIKI KAISHA, Tokyo (JP)

(72) Inventor: Hironobu HIRATA, Tokyo (JP)

(73) Assignee: USHIO DENKI KABUSHIKI KAISHA, Tokyo (JP)

(21) Appl. No.: 19/160,238

(22) PCT Filed: Nov. 21, 2023
(86) PCT No.: PCT/JP2023/041817

§ 371 Date: Aug. 27, 2025

(30) Foreign Application Priority Data
Mar. 1, 2023 (JP) 2023-030807

(51) Int. Cl. H05G 2/00; G03F 1/22; G03F 7/00; G03F 7/20

(52) U.S. Cl. CPC H05G 2/0094; G03F 1/22; G03F 7/2004; G03F 7/70033; G03F 7/709; G03F 7/70916

(57) ABSTRACT

Provided are a debris trap unit and a light source apparatus that can improve the efficiency of maintenance of a foil trap. A debris trap unit according to one embodiment of the present invention includes a detachable member and at least one foil trap. The debris trap unit is attached to an opening of a chamber main body including an output port for radiation from plasma and the opening different from the output port. The detachable member covers the opening and is configured to be attachable/detachable to/from the chamber main body. The at least one foil trap includes a plurality of foils to capture debris from the plasma, and is connected to the detachable member such that the plurality of foils are disposed on a path of the radiation from the plasma to the output port with the detachable member being attached to the chamber main body.

### TECHNICAL FIELD

The present invention relates to a debris trap unit that captures debris emitted from plasma and to a light source apparatus.

### BACKGROUND ART

X-rays have been conventionally used for medical, industrial, and research applications.

In the medical field, X-rays are used for such applications as chest radiography, dental radiography, and computer tomogram (CT).

In the industrial field, X-rays are used for such applications as non-destructive testing and tomographic non-destructive testing to observe the inside of materials such as structures and welds.

In the research field, X-rays are used for such applications as X-ray diffraction to analyze the crystal structure of materials and X-ray spectroscopy (X-ray fluorescence analysis) to analyze the constituent composition of materials.

Extreme ultraviolet light (hereinafter referred to as EUV light) having a wavelength of 13.5 nm, which is in the soft X-ray region having a relatively long wavelength among X-rays, has been recently used for exposure light.

Here, the base material of an EUV lithography mask including fine patterns is a reflective mirror having a stacked structure in which a multilayer film (e.g., molybdenum and silicon) for reflecting EUV light is provided on a substrate made of low-thermal-expansion glass.

A material that absorbs radiation having a wavelength of 13.5 nm is then patterned on the multilayer film, so that an EUV mask is formed.

In addition, the size of unacceptable defects in EUV masks is much smaller than that of conventional ArF masks, and the unacceptable defects are difficult to detect.

In this regard, EUV masks are inspected using radiation having a wavelength that matches the wavelength operated in lithography, which is usually called an actinic inspection.

For example, when performed using radiation having a wavelength of 13.5 nm, the actinic inspection can detect defects with resolution better than 10 nm.

EUV light source apparatuses generally include a discharge produced plasma (DPP) light source apparatus, a laser assisted discharge produced plasma (LDP) light source apparatus, and a laser produced plasma (LPP) light source apparatus.

The DPP light source apparatus applies high voltage between electrodes between which a gaseous plasma raw material (discharge gas) containing EUV radiation species is supplied to generate a high-density high-temperature plasma by the discharge, thereby utilizing the extreme ultraviolet light radiated from the plasma.

The LDP light source apparatus is obtained by improving the DPP light source apparatus. For example, a liquid high-temperature plasma raw material (e.g., Sn (tin), Li (lithium), etc.) containing EUV radiation species is supplied to the surface of the electrode (discharge electrode) at which discharge is generated. The material is then irradiated with an energy beam (e.g., electron beam, laser beam, etc.) to vaporize the material, and then high-temperature plasma is generated by discharge.

The LPP light source apparatus generates high-temperature plasma by exciting EUV radiation species by a laser beam or the like. As this type of light source apparatuses, a light source apparatus is known, which generates plasma by condensing a laser beam on a droplet of Sn (tin) or Li (lithium) that has been ejected in the form of a minute liquid droplet, which is a target material for EUV radiation, and by exciting the target material. In addition, as the LPP light source apparatus, there is known an apparatus that supplies a liquid high-temperature plasma raw material containing EUV radiation species to a surface of a rotating body and irradiates the surface of the rotating body with an energy beam (laser beam) to generate plasma.

In such manner, the method of generating EUV light using plasma is also applicable to an apparatus that generates not only EUV light but also X-rays having a wavelength shorter than that of the EUV light by changing the type of plasma raw materials or excitation energy for generating plasma.

By the way, debris is dissipated at high speed from the plasma generated by those light source apparatuses. This debris contains particles of a high-temperature plasma raw material, material particles of electrodes and rotating bodies sputtered along with the plasma generation, and the like. If such debris reaches an utilization apparatus that uses radiation such as EUV light, it may damage or contaminate optical elements such as a reflective film provided in the utilization apparatus. As a result, the performance of the utilization apparatus may be degraded.

In this regard, in order to prevent the debris dissipated from plasma from entering the utilization apparatus, a debris mitigation device (also referred to as debris mitigation tool (DMT)) that captures debris between the plasma and the utilization apparatus is proposed. The debris mitigation device is typically configured by using a foil trap. The foil trap is a debris trap that captures debris by using a thin plate-like foil.

For example, Patent Literature 1 describes a fixed foil trap and a rotary foil trap. The rotary foil trap rotates a plurality of foils radially disposed with a rotation shaft as the center, and causes the debris and the foils to collide with each other to capture debris. The fixed foil trap divides a space by a plurality of foils located at fixed positions, increases the pressure of atmosphere gas in that space, and causes the debris and the atmosphere gas to collide with each other to capture debris. Use of those foil traps makes it possible to capture particles with a small number of constituent atoms, atoms in neutral or ionic states, and the like, from micrometer-sized droplets belonging to a relatively large size category among debris.

### CITATION LIST

### Patent Literature

Patent Literature 1: Japanese Patent Application Laid-open No. 2017-219698

### DISCLOSURE OF INVENTION

### Technical Problem

Debris that has entered the foil trap adheres to, for example, the foils and the members around the foils and flows down to be collected into a storage container, but some debris remains adhering to the foils and the like. For example, as an operation time increases, the amount of debris adhering to the foils may increase, and a debris capture rate by the foil trap may deteriorate. In addition, in a rotary foil trap, the weight of the foils increases due to the adhesion of debris, which may cause unstable rotation.

For that reason, when the foil trap is used, maintenance such as removal of debris adhering to the foils and the like or replacement of the foil trap is required. As described above, the foil trap is provided between a light source portion that generates plasma and a utilization apparatus. Hence, in order to detach the foil trap, for example, it is necessary to detach and disassemble the light source portion or the like and perform adjustment after assembly, resulting in time-consuming maintenance of the foil trap.

In view of the circumstances as described above, it is an object of the present invention to provide a debris trap unit and a light source apparatus that can improve the efficiency of maintenance of a foil trap.

### Solution to Problem

In order to achieve the above object, a debris trap unit according to one embodiment of the present invention includes a detachable member and at least one foil trap.

The debris trap unit is attached to an opening of a chamber main body including an output port for radiation from plasma and the opening different from the output port.

The detachable member covers the opening and is configured to be attachable/detachable to/from the chamber main body.

The at least one foil trap includes a plurality of foils to capture debris from the plasma, and is connected to the detachable member such that the plurality of foils are disposed on a path of the radiation from the plasma to the output port with the detachable member being attached to the chamber main body.

In this debris trap unit, the at least one foil trap including the plurality of foils to capture debris from the plasma is connected to the detachable member that covers the opening of the chamber main body and is attached/detached to/from the chamber main body. In the state in which the detachable member is attached, the plurality of foils are disposed on the path of the radiation from the plasma to the output port. In addition, when the detachable member is detached, the foil trap can be detached together. This makes it possible to improve the efficiency of maintenance of the foil trap.

The at least one foil trap may include a rotary foil trap including the plurality of foils and a rotary member that radially supports the plurality of foils. In this case, the debris trap unit may further include: a shaft portion that is connected to the rotary member of the rotary foil trap; and a rotation drive portion that rotates the shaft portion.

The rotation drive portion may be connected to an outside of the detachable member. In this case, the shaft portion may penetrate the detachable member. In addition, the rotary member may be connected to the shaft portion inside the detachable member.

The debris trap unit may further include a reinforcement member that is configured as a separate member from the detachable member and fixes the rotation drive portion to the detachable member.

The detachable member may include a reinforcement portion that reinforces rigidity of a portion to which the rotation drive portion is connected.

The at least one foil trap may include a fixed foil trap including the plurality of foils and a fixed member that fixes the plurality of foils.

The debris trap unit may further include a foil trap cover that is connected to the detachable member, encloses an outer circumferential portion of the rotary foil trap, and collects the debris scattered from the rotary foil trap. In this case, the fixed foil trap may be connected to the foil trap cover.

The debris trap unit may further include a gas introduction pipe that penetrates the detachable member and introduces a transparent gas to the fixed foil trap, the transparent gas being transparent to the radiation.

The debris trap unit may further include a condensing mirror that is connected to the detachable member and condenses the radiation from the plasma. In this case, the at least one foil trap is disposed between the plasma and the condensing mirror.

The debris trap unit may further include a position adjustment mechanism that adjusts arrangement of the condensing mirror.

The debris trap unit may further include a vibration-isolation mechanism that suppresses vibration transmitted to the chamber main body and/or the condensing mirror.

The debris trap unit may further include at least one of a heat shielding member that is connected to the detachable member and is disposed between the plasma and the foil trap, or a detection sensor that is connected to the detachable member and detects a state of the plasma.

The detachable member may include a guide mechanism that guides an attaching position with respect to the chamber main body.

A light source apparatus according to one embodiment of the present invention includes a plasma generation section, a chamber main body, and the debris trap unit described above.

The plasma generation section converts a plasma raw material into plasma.

The chamber main body includes an output port for radiation from plasma generated by the plasma generation section, and an opening different from the output port.

### Advantageous Effects of Invention

As described above, according to the present invention, it is possible to improve the efficiency of maintenance of a foil trap. Note that the effects described herein are not necessarily limitative, and any effect described in the present disclosure may be provided.

### BRIEF DESCRIPTION OF DRAWINGS

FIG. 1 is a schematic cross-sectional view showing a configuration of an EUV light source apparatus including a debris trap unit according to a first embodiment of the present invention.

FIG. 2 is a schematic view showing a configuration example of the debris trap unit according to the first embodiment.

FIG. 3 is a schematic view showing a state in which the debris trap unit is detached.

FIG. 4 is a schematic cross-sectional view showing a configuration example of a rotary foil trap.

FIG. 5 a schematic front view showing a configuration example of the rotary foil trap.

FIG. 6 is a schematic view showing another configuration example of the debris trap unit.

FIG. 7 is a schematic view showing another configuration example of the debris trap unit.

FIG. 8 is a schematic cross-sectional view showing a configuration example of a fixed foil trap.

FIG. 9 is a schematic front view showing a configuration example of the fixed foil trap.

FIG. 10 is a schematic view showing a configuration example of a debris trap unit including a foil trap cover.

FIG. 11 is a schematic view showing a configuration example of a debris trap unit including a heat shielding plate.

FIG. 12 is a schematic cross-sectional view showing a configuration example of an EUV light source apparatus including a debris trap unit according to a second embodiment.

FIG. 13 is a schematic plan view showing a configuration example of an RFT supporting portion.

FIG. 14 is a schematic perspective view showing a configuration example of a condensing mirror.

FIG. 15 is a schematic view showing another configuration example of the debris trap unit including the condensing mirror.

FIG. 16 is a schematic view showing another configuration example of the debris trap unit including the condensing mirror.

FIG. 17 is a schematic view showing another configuration example of the debris trap unit including the condensing mirror.

### MODE(S) FOR CARRYING OUT THE INVENTION

Hereinafter, embodiments according to the present invention will be described with reference to the drawings.

### First Embodiment

### Configuration of Light Source Apparatus

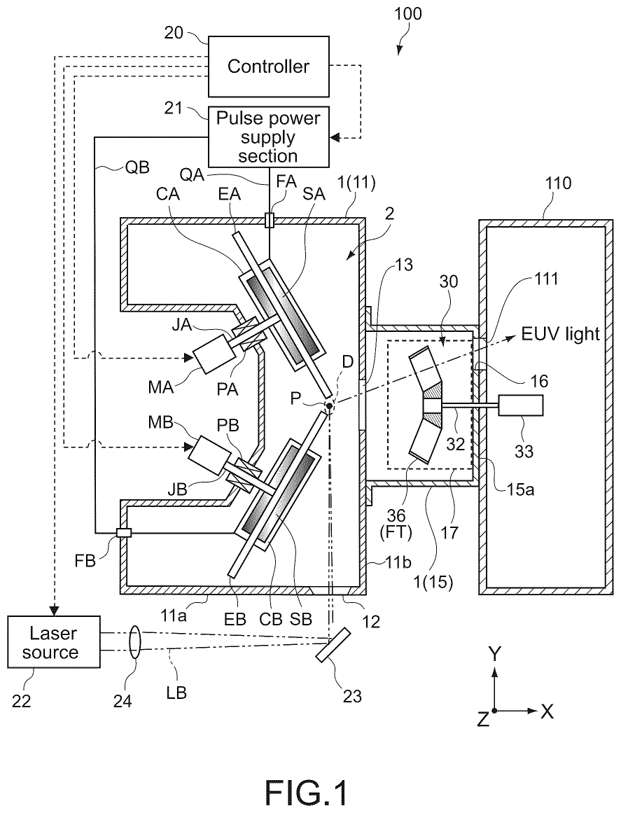

FIG. 1 is a schematic cross-sectional view showing a configuration of an EUV light source apparatus including a debris trap unit according to a first embodiment of the present invention. In this embodiment, as an EUV light source apparatus 100, a laser assisted discharge produced plasma (LDP) extreme ultraviolet light source apparatus (EUV light source apparatus) will be described as an example. In addition, the EUV light source apparatus 100 is connected to a utilization apparatus 110 that uses EUV light, and functions as a light source of the utilization apparatus 110.

Note that in the figure the X-axis, the Y-axis, and the Z-axis indicate three axial directions orthogonal to each other, and the Z-axis corresponds to a vertical direction (gravity direction). Therefore, FIG. 1 is a cross-sectional view of the EUV light source apparatus 100 taken along the horizontal direction.

### Overall Configuration

In FIG. 1, the EUV light source apparatus 100 emits extreme ultraviolet light (EUV light). The wavelength of this extreme ultraviolet light is, for example, 13.5 nm.

Specifically, the EUV light source apparatus 100 irradiates liquid-phase plasma raw materials SA and SB, which are respectively supplied to the surfaces of a pair of discharge electrodes EA and EB that generate discharge, with an energy beam such as a laser beam LB, to vaporize the plasma raw materials SA and SB. After that, plasma P is generated by discharge in a discharge region D between the discharge electrodes EA and EB. EUV light is emitted from the plasma P.

The utilization apparatus 110 is, for example, a mask inspection apparatus used in lithography. In this case, part of the EUV light emitted from the plasma P is extracted from an output port 16 (light extraction section) and guided to the mask inspection apparatus. The mask inspection apparatus uses the EUV light emitted from the output port 16 of the EUV light source apparatus 100 as inspection light to perform a mask blank inspection or pattern inspection. Use of EUV light can support 5 nm to 7 nm processes.

In this embodiment, the EUV light corresponds to radiation extracted from plasma, and the EUV light source apparatus 100 corresponds to a light source apparatus. In addition, the mask inspection apparatus is an example of a utilization apparatus that uses radiation from plasma.

The EUV light source apparatus 100 includes a chamber main body 1, a light source section 2, a debris trap unit 30, and a debris storage section not shown in the figure. The light source section 2 generates EUV light on the basis of the LDP method in the chamber main body 1. The debris trap unit 30 is a debris mitigation device that is attached to the chamber main body 1 and captures debris DB scattered together with the EUV light emitted from the light source section 2. The debris storage section stores debris generated by the light source section 2, debris captured by the debris trap unit 30, and the like.

### Chamber Main Body

The chamber main body 1 is a main body of a vacuum enclosure (vacuum chamber) that generates plasma P and maintains a reduced-pressure atmosphere for extracting EUV light coming from the plasma P. The chamber main body 1 is connected to the utilization apparatus 110 (mask inspection apparatus) that uses EUV light.

As shown in FIG. 1, in this embodiment, the chamber main body 1 includes a light source chamber 11 and a connection chamber 15.

The light source chamber 11 is a reduced-pressure container that separates plasma P generated inside from the outside.

The light source chamber 11 forms a plasma generation chamber that houses the light source section 2 that generates plasma P. The light source chamber 11 is a vacuum enclosure made of a rigid body, e.g., metal, and its interior is maintained in a reduced-pressure atmosphere of a predetermined pressure or below by a vacuum pump (not shown) in order to successfully generate discharge for heating and exciting the plasma raw materials SA and SB and to suppress the attenuation of EUV light.

A transparent window 12 for introducing the laser beam LB is provided in a side wall 11a of the light source chamber 11. In addition, a through-hole 13 that communicates with the connection chamber 15 is provided in a side wall 11b of the light source chamber 11.

The connection chamber 15 is a reduced-pressure container that connects the light source chamber 11 and the utilization apparatus 110 to each other. The connection chamber 15 is connected to the side wall 11b of the light source chamber 11, and the internal space of the connection chamber 15 communicates with the internal space of the light source chamber 11 via the through-hole 13. The connection chamber 15 is a vacuum enclosure made of a rigid body, e.g., metal, and its interior is maintained in a reduced-pressure atmosphere of a predetermined pressure or below in order to suppress the attenuation of EUV light, as in the light source chamber 11.

The connection chamber 15 includes the output port 16 and an opening 17.

The output port 16 is an optical window for introducing the EUV light incident from the through-hole 13 into the utilization apparatus 110, and functions as a light extraction section that extracts the EUV light in the EUV light source apparatus 100. In the example shown in FIG. 1, the output port 16 is provided in a side wall 15a of the connection chamber 15.

The opening 17 is an attachment port to which the debris trap unit 30 is attached, and is provided at a different position from the output port 16. In FIG. 1, the opening 17 is schematically shown by the dotted line region.

In such a manner, the chamber main body 1 (connection chamber 15) includes the output port 16 for the EUV light from the plasma P, and the opening 17 different from the output port 16. In addition, the debris trap unit 30 to be described later is attached to the opening 17.

Note that two chambers (light source chamber 11 and connection chamber 15) are connected to each other to constitute the chamber main body 1 in the example shown in FIG. 1. The chamber main body 1 is not limited to the above, and for example, it may be configured as a vacuum enclosure using a single member or may be configured by combining two or more members so as to constitute a single vacuum enclosure as a whole.

### Light Source Section

The light source section 2 converts the plasma raw material into plasma to generate plasma P from which EUV light is emitted. In this embodiment, the light source section 2 corresponds to a plasma generation section that converts a plasma raw material into plasma.

The light source section 2 includes the pair of discharge electrodes EA and EB. The discharge electrodes EA and EB are disc-shaped members having the same shape and size. For example, the discharge electrode EA is used as a cathode and the discharge electrode EB is used as an anode. The discharge electrodes EA and EB are made of, for example, a high-melting-point metal such as molybdenum (Mo), tungsten (W), or tantalum (Ta). The discharge electrodes EA and EB are disposed apart from each other, and circumferential portions of the discharge electrodes EA and EB are in proximity to each other.

At that time, the discharge region D in which the plasma P is generated is located in a gap between the discharge electrodes EA and EB, in which the circumferential portions of the discharge electrodes EA and EB are closest to each other.

A container CA in which the liquid-phase plasma raw material SA is accumulated, and a container CB in which the liquid-phase plasma raw material SB is accumulated, are disposed inside the light source chamber 11. Heated liquid-phase plasma raw materials SA and SB are supplied to the containers CA and CB, respectively. The liquid-phase plasma raw materials SA and SB are, for example, tin (Sn), but may also be lithium (Li).

The container CA stores the liquid-phase plasma raw material SA such that the lower part of the discharge electrode EA is immersed in the plasma raw material SA. The container CB stores the liquid-phase plasma raw material SB such that the lower part of the discharge electrode EB is immersed in the plasma raw material SB. Therefore, the liquid-phase plasma raw materials SA and SB adhere to the lower parts of the discharge electrodes EA and EB, respectively. The liquid-phase plasma raw materials SA and SB, which have adhered to the lower parts of the discharge electrodes EA and EB, respectively, are transported to the discharge region D, in which plasma P is to be generated, along with the rotation of the discharge electrodes EA and EB.

The discharge electrode EA is coupled to a rotation shaft JA of a motor MA and rotates around an axis of the discharge electrode EA. The discharge electrode EB is coupled to a rotation shaft JB of a motor MB and rotates around an axis of the discharge electrode EB. The motors MA and MB are disposed outside the light source chamber 11, and the rotation shafts JA and JB of the respective motors MA and MB penetrate the light source chamber 11 to extend from the outside to the inside of the light source chamber 11. The clearance between the rotation shaft JA and the wall of the light source chamber 11 is sealed with a seal member PA, and the clearance between the rotation shaft JB and the wall of the light source chamber 11 is sealed with a seal member PB. The seal members PA and PB are, for example, mechanical seals. The seal members PA and PB rotatably support the rotation shafts JA and JB, respectively, while maintaining a reduced-pressure atmosphere within the light source chamber 11.

The EUV light source apparatus 100 further includes a controller 20, a pulse power supply section 21, a laser source (energy beam irradiation device) 22, and a movable mirror 23. The controller 20, the pulse power supply section 21, the laser source 22, and the movable mirror 23 are installed outside the light source chamber 11. The controller 20 controls the operation of each section of the EUV light source apparatus 100 as will be described later. For example, the controller 20 controls the rotation drive of the motors MA and MB to rotate the discharge electrodes EA and EB at a predetermined rotation speed. In addition, the controller 20 controls the operation of the pulse power supply section 21, the irradiation timing of the laser beam LB from the laser source 22, and the like.

Two power feed lines QA and QB extending from the pulse power supply section 21 pass through feedthroughs FA and FB, respectively, and are connected to the containers CA and CB disposed inside the light source chamber 11, respectively. The feedthroughs FA and FB are seal members that are embedded in the wall of the light source chamber 11 to maintain a reduced-pressure atmosphere within the light source chamber 11. The containers CA and CB are formed of an electrically conductive material, and the plasma raw materials SA and SB respectively stored inside the containers CA and CB are also electrically conductive materials such as tin. The lower parts of the discharge electrodes EA and EB are immersed in the plasma raw materials SA and SB stored inside the containers CA and CB, respectively. Therefore, when the pulse power supply section 21 supplies pulse power to the containers CA and CB, that pulse power is supplied to the discharge electrodes EA and EB via the plasma raw materials SA and SB, respectively.

The pulse power supply section 21 supplies the pulse power to the discharge electrodes EA and EB to generate discharge in the discharge region D. The plasma raw materials SA and SB transported to the discharge region D along the rotation of the discharge electrodes EA and EB are then heated and excited by an electric current flowing between the discharge electrodes EA and EB during discharge, so that plasma P from which EUV light is to be emitted is generated.

The laser source 22 irradiates the plasma raw material SA that has adhered to the discharge electrode EA and has been transported to the discharge region D with the laser beam to vaporize the plasma raw material SA. The laser source 22 is, for example, a Nd: YVO₄ (Neodymium-doped Yttrium Orthovanadate) laser apparatus.

At that time, the laser source 22 emits the laser beam LB in the infrared region having a wavelength of 1064 nm.

However, the energy beam irradiation device may be a device that emits an energy beam other than the laser beam LB, provided that it can vaporize the plasma raw material SA.

The laser beam LB emitted from the laser source 22 is guided to, for example, the movable mirror 23 via condensing means including a condensing lens 24. The condensing means adjusts a spot diameter of the laser beam LB at a laser beam irradiation position of the discharge electrode EA. The condensing lens 24 and the movable mirror 23 are disposed outside the light source chamber 11.

The laser beam LB that has been condensed by the condensing lens 24 is reflected by the movable mirror 23, passes through the transparent window 12 provided in the side wall 11a of the light source chamber 11, and is applied to the discharge electrode EA near the discharge region D. The position of the discharge electrode EA at which the laser beam LB is applied is adjusted by adjusting the posture of the movable mirror 23. Note that the adjustment of the posture of the movable mirror 23 may be manually performed by an operator, or the controller 20 may control the posture of the movable mirror 23 on the basis of intensity information of EUV light from a detection sensor 82 to be described later. In this case, the movable mirror 23 is driven by a movable mirror drive section, illustration of which is omitted.

In order to facilitate the irradiation of the laser beam LB onto the circumferential portion of the discharge electrode EA near the discharge region D, the axes of the discharge electrodes EA and EB are not aligned in parallel. The interval between the rotation shafts JA and JB is narrower on the side of the motors MA and MB, and is wider on the side of the discharge electrodes EA and EB. This makes it possible to bring the facing surfaces of the discharge electrodes EA and EB closer to each other while retracting the opposite sides of the facing surfaces of the discharge electrodes EA and EB from the irradiation path of the laser beam LB, thereby making it easier to irradiate the circumferential portion of the discharge electrode EA near the discharge region D with the laser beam LB.

The discharge electrode EB is disposed between the discharge electrode EA and the movable mirror 23. The laser beam LB that has been reflected by the movable mirror 23 passes near the outer circumferential surface of the discharge electrode EB and then reaches the outer circumferential surface of the discharge electrode EA. At that time, in order to prevent the laser beam LB from being blocked by the discharge electrode EB, the discharge electrode EB is retracted in the direction of the motor MB side (left side of FIG. 1) relative to the discharge electrode EA. The liquid-phase plasma raw material SA that has adhered to the outer circumferential surface of the discharge electrode EA near the discharge region D is vaporized by the irradiation of the laser beam LB and is supplied to the discharge region D as a gas-phase plasma raw material SA.

The pulse power supply section 21 supplies power to the discharge electrodes EA and EB so as to generate the plasma P in the discharge region D (to convert the gas-phase plasma raw material SA into plasma). When the gas-phase plasma raw material SA is supplied to the discharge region D by the irradiation of the laser beam LB, discharge is generated between the discharge electrodes EA and EB in the discharge region D. When discharge is generated between the discharge electrodes EA and EB, the gas-phase plasma material SA in the discharge region D is heated and excited by an electric current, thereby generating the plasma P. EUV light emitted from the generated plasma P enters the connection chamber 15 through the through-hole 13 provided in the side wall 11b of the light source chamber 11.

### Configuration of Debris Trap Unit

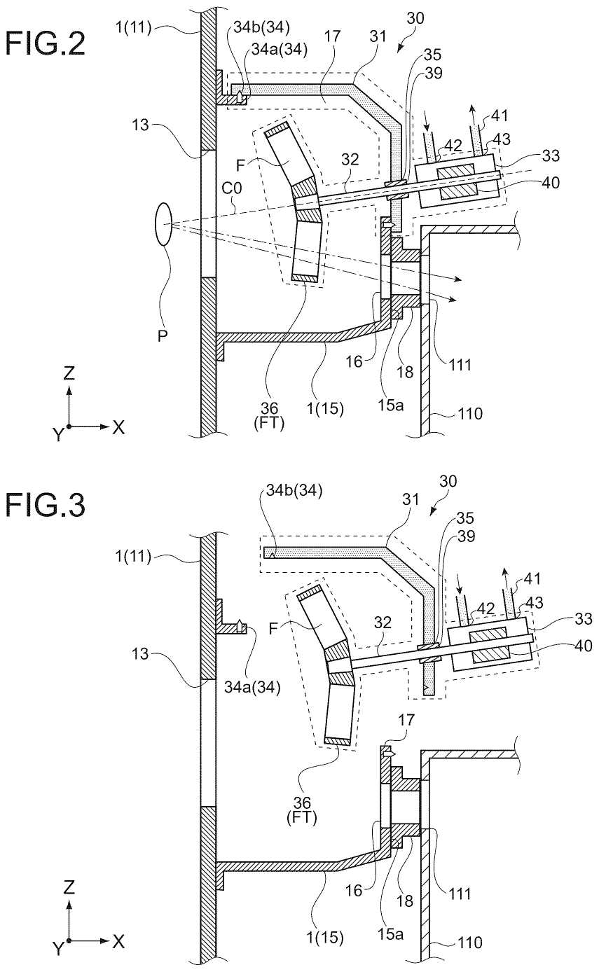

FIG. 2 is a schematic view showing a configuration example of the debris trap unit according to the first embodiment.

FIG. 3 is a schematic view showing a state in which the debris trap unit is detached. FIGS. 2 and 3 are cross-sectional views of the EUV light source apparatus 100 shown in FIG. 1 taken along the vertical direction. Here, the illustration of the light source section 2 that generates plasma P is omitted.

First, a configuration of the connection chamber 15 (chamber main body 1) to which the debris trap unit 30 is attached will be described with reference to FIG. 2.

As described above, the connection chamber 15 includes the output port 16 for EUV light and the opening 17 to which the debris trap unit 30 is attached.

The output port 16 is typically a through-hole and is connected to an input port 111 for EUV light that is provided to the outside of the utilization apparatus 110. In this case, the internal space of the connection chamber 15 communicates with the internal space of the utilization apparatus 110 via the output port 16.

In the example of FIG. 2, the output port 16 is provided to the lower side of the side wall 15a of the connection chamber 15, and EUV light travelling from the plasma P to the lower right of the figure is extracted from the output port 16. In addition, a connection flange 18 that connects the output port 16 and the input port 111 of the utilization apparatus 110 to each other is provided. The opening diameters of the output port 16 and the connection flange 18 are set as appropriate in accordance with the beam diameter of the EUV light that is output to the utilization apparatus 110, or the like.

Note that the output port 16 may be provided with, for example, a transparent member such as an optical filter that passes the EUV light therethrough. In addition, a valve, a gate, or the like to open and close the path from the connection chamber 15 to the utilization apparatus 110 may be provided. Such a configuration makes it possible to independently operate the reduced-pressure atmosphere on the EUV light source apparatus 100 side and the reduced-pressure atmosphere on the utilization apparatus 110 side. This makes it possible to, for example, open the connection chamber 15 to atmosphere while maintaining the reduced-pressure atmosphere within the utilization apparatus 110, thereby facilitating maintenance.

The opening 17 is provided to the connection chamber 15 so as to be capable of adding and removing the contents of the debris trap unit 30. As shown in FIG. 2, in this embodiment, the opening 17 is provided from the top of the connection chamber 15 to the side wall 15a in which the output port 16 is provided. The shape, size, position, or the like of the opening 17 is not limited and may be set as appropriate in accordance with the optical path of the EUV light, the configurations of the light source section 2 and the debris trap unit 30, and the like.

The debris trap unit 30 is attached to the opening 17 of the connection chamber 15 (chamber main body 1) and captures debris DB dissipated from the plasma P. In other words, the debris trap unit 30 is a debris mitigation device DMT that is attached to the chamber main body 1 for use. The debris trap unit 30 includes a detachable member 31, a foil trap FT, a rotation shaft 32, and a rotation drive portion 33.

### Detachable Member

The detachable member 31 is a member that covers the opening 17 and is configured to be attachable/detachable to/from the connection chamber 15 (chamber main body 1). In other words, the detachable member 31 functions as a lid to close the opening 17 and also as an outer wall of the vacuum enclosure configured by the connection chamber 15.

In the following, the side of the detachable member 31 that faces the inside of the chamber will be described as the inside of the detachable member 31, and the opposite side will be described as the outside of the detachable member 31.

The detachable member 31 is a structural member made of metal, and is configured to be capable of supporting the foil trap FT, the rotation shaft 32, and the rotation drive portion 33 while maintaining the reduced-pressure atmosphere inside the connection chamber 15. Aluminum or the like is used as the material of the detachable member 31. In addition, a seal member, illustration of which is omitted, is provided at the location where the detachable member 31 and the connection chamber 15 come into contact with each other so as to avoid leakage and maintain the reduced-pressure atmosphere.

In the example of FIG. 2, the detachable member 31 having an L-shaped cross-section is attached so as to cover the opening 17 provided from the top of the connection chamber 15 to the side thereof. The detachable member 31 is typically fixed to the connection chamber 15 by screwing.

The specific shape of the detachable member 31 is not limited. For example, if the connection chamber 15 shown in FIG. 2 has a cylindrical shape with a bottom as a whole, the detachable member 31 has a shape obtained by cutting out a portion including a side surface and a bottom surface of the cylindrical column. In addition, if the connection chamber 15 has a rectangular parallelepiped shape as a whole, the detachable member 31 has an L-shape obtained by cutting out a rectangular parallelepiped including two surfaces orthogonal to each other. In addition, if the opening 17 is provided on the plane, the detachable member 31 is a flat plate-like member that closes the opening 17.

In addition, the detachable member 31 includes a guide mechanism 34 that guides an attaching position with respect to the connection chamber 15 (chamber main body 1). In the example of FIG. 2, a guide pin 34a and a guide hole 34b configured to be fitted to each other are used as the guide mechanism 34. For example, the guide pin 34a is provided at a position at which the guide pin 34a comes into contact with the detachable member 31 on the outside of the connection chamber 15. The guide hole 34b into which each guide pin 34a is to be inserted is provided on the inside of the detachable member 31. Note that the specific configuration of the guide mechanism 34 is not limited, and for example, a slit and a rib configured to be fitted to each other may be used.

The guide mechanism 34 is provided, so that the detachable member 31 can be attached to a predetermined attaching position accurately. In addition, when the detachable member 31 is attached, the adjustment of the attaching position or the like is almost unnecessary to perform. Hence, this makes it possible to avoid, for example, a situation in which the seal member is damaged by shifting the detachable member 31 for alignment.

Note that the guide mechanism 34 is not necessarily required to be provided.

In addition, the detachable member 31 is provided with a through-hole 35. This through-hole 35 is a hole for passing the rotation shaft 32 therethrough. Additionally, a handle or the like for supporting the entire debris trap unit 30 may be provided to the outside of the detachable member 31.

### Foil Trap

The debris DB is dissipated in various directions at high speed, together with the EUV light, from the plasma P generated in the light source section 2. The debris DB contains Sn particles that are the plasma raw materials SA and SB, and material particles of the discharge electrodes EA and EB sputtered along with the generation of the plasma P. The debris DB obtains large kinetic energy through the contraction and expansion processes of the plasma P. In other words, the debris DB generated from the plasma P contains fast-moving ions, neutral particles, and electrons. If such debris DB reaches the utilization apparatus 110, the debris DB may damage or contaminate a reflective film and the like of the optical elements in the utilization apparatus 110, thereby degrading its performance.

In this regard, the debris trap unit 30 is provided with a foil trap FT in order to prevent the debris DB from entering the utilization apparatus 110. The foil trap FT is a debris trap that is disposed inside the connection chamber 15 (chamber main body 1) and captures the debris DB from the plasma P using a plurality of foils F. Use of the foil trap FT makes it possible to capture debris, for example, ranging from large debris of millimeter size to small debris of atomic size. In this embodiment, the portion that includes a plurality of foils F and captures the debris DB will be referred to as a foil trap FT.

The foil trap FT is connected to the detachable member 31 such that the plurality of foils F are disposed on the path of the EUV light from the plasma P to the output port 16 with the detachable member 31 being attached to the connection chamber 15 (chamber main body 1).

Here, the path of the EUV light from the plasma P to the output port 16 refers to a path on which the EUV light emitted from the output port 16 passes. In the example shown in FIG. 2, a liner path that directly connects from the plasma P to the output port 16 is formed. The plurality of foils F are disposed on this path.

Note that the plurality of foils F are not necessarily disposed on a straight line connecting the plasma P and the output port 16. For example, a reflective mirror or the like to change the output direction of the EUV light may be provided in the connection chamber 15. In this case, the plurality of foils F are disposed on the path of the EUV light between the plasma P and the reflective mirror to capture the debris DB toward the reflective mirror.

In addition, the fact that the foil trap FT is connected to the detachable member 31 means that the foil trap FT including the plurality of foils F is directly or indirectly connected to the detachable member 31. Typically, the foil trap FT and the detachable member 31 are indirectly connected to each other via one or more members, but a configuration in which the foil trap FT is directly connected to the detachable member 31 is also conceivable, for example.

The foil trap FT and the detachable member 31 are connected to each other, so that the foil trap FT can also be attached/detached together with the detachable member 31.

As the foil trap FT, a rotary foil trap provided with an action that causes the plurality of foils F to actively collide with debris, and a fixed foil trap in which the positions of the plurality of foils F are fixed are exemplified. The rotary foil trap is also referred to as a rotating foil trap (RFT). In addition, the fixed foil trap is also referred to as a static foil trap (SFT).

In FIG. 2, the case where only a rotary foil trap 36 is mounted will be described as an example of the debris trap unit 30. Note that a debris trap unit equipped with both the rotary foil trap 36 and a fixed foil trap (see FIG. 7 etc.), and a debris trap unit equipped with only a fixed foil trap may be configured.

### Rotary Foil Trap

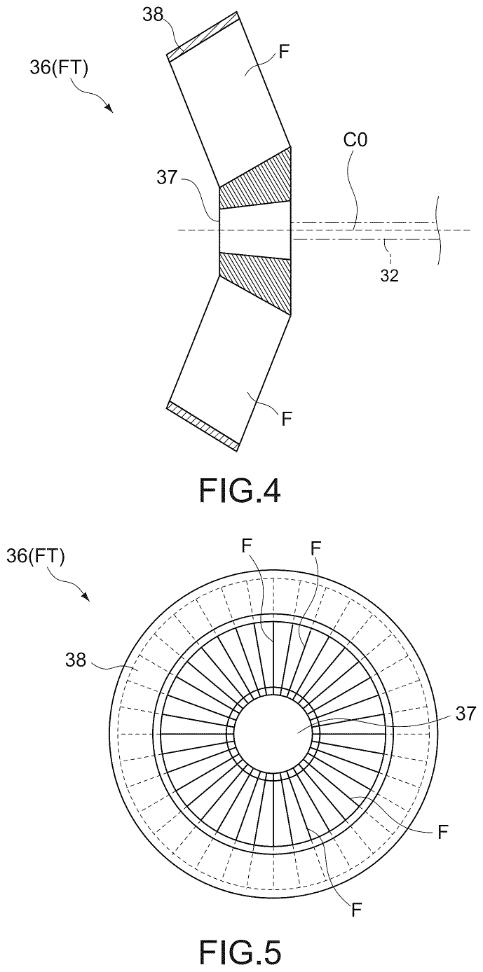

FIG. 4 is a schematic cross-sectional view showing a configuration example of the rotary foil trap 36. FIG. 5 is a schematic front view showing a configuration example of the rotary foil trap 36. As shown in FIGS. 4 and 5, the rotary foil trap 36 includes a plurality of foils (blades) F, a central support post 37, and an outer ring 38.

Each of the plurality of foils F is a thin film or thin flat plate. The central support post 37 is a member that radially supports the plurality of foils F. The outer ring 38 is disposed concentrically with the central support post 37 and is connected to the tip of each foil F radially extending from the central support post 37. In this embodiment, the central support post 37 corresponds to a rotary member.

Each foil F is radially disposed around the central support post 37 at almost equal angular intervals.

At that time, each foil F is on the plane containing the central axis C0 of the central support post 37. The material of the rotary foil trap 36 is, for example, a high-melting-point metal such as tungsten (W) or molybdenum (Mo).

As shown in FIG. 5, the plurality of foils F of the rotary foil trap 36 are disposed parallel to the light beam direction of the EUV light so as not to block the EUV light coming from the plasma P (emission point) toward the output port 16. In other words, the rotary foil trap 36 in which each foil F is disposed on the plane containing the central axis C0 of the central support post 37 is disposed such that the plasma P (emission point) exists on the extension of the central axis C0 of the central support post 37 (see FIG. 2). Thus, the EUV light is blocked only by the thickness of each foil F, except for the central support post 37 and the outer ring 38, which makes it possible to maximize the proportion of EUV light that passes through the rotary foil trap 36 (also referred to as transmittance).

### Rotation Shaft

Returning to FIG. 2, the rotation shaft 32 is a columnar long member and is connected to the central support post 37 of the rotary foil trap 36. In this embodiment, the rotation shaft 32 corresponds to a shaft portion.

In this embodiment, the rotation shaft 32 is disposed to pass through the through-hole 35 of the detachable member 31.

The central support post 37 of the rotary foil trap 36 is connected to an end portion of the rotation shaft 32 disposed inside the detachable member 31. Specifically, the rotation shaft 32 and the central support post 37 are connected to each other such that the central axis of the rotation shaft 32 and the central axis C0 of the central support post 37 are aligned with each other. In addition, the rotation drive portion 33 is connected to an end portion of the rotation shaft 32 disposed inside the detachable member 31 (an end portion opposite to the side to which the rotary foil trap 36 is connected).

In addition, the debris trap unit 30 has a structure to receive the rotation shaft 32 with a mechanical seal 39. As shown in FIG. 2, the through-hole 35 provided in the detachable member 31 is designed to be larger than the diameter of the rotation shaft 32. The clearance between the rotation shaft 32 and the through-hole 35 is sealed by the mechanical seal 39. The mechanical seal 39 rotatably supports the rotation shaft 32 of a motor 40 while maintaining the reduced-pressure atmosphere within the connection chamber 15.

### Rotation Drive Portion

The rotation drive portion 33 is a drive mechanism that rotates the rotation shaft 32 and functions as a control unit that controls rotation of the rotary foil trap 36. For example, the rotation speed or the like of the rotary foil trap 36 is controlled by the rotation drive portion 33 as appropriate. In addition, the rotation drive portion 33 is fixed to the outside of the detachable member 31 by a fixed member not shown in the figure such that the rotation drive portion 33 itself does not rotate with respect to the detachable member 31.

The rotation drive portion 33 includes the motor 40 and a cooling mechanism, illustration of which is omitted.

The motor 40 is connected to the rotation shaft 32 and rotates the rotation shaft 32 around the central axis thereof. Therefore, the rotation shaft 32 of the motor 40 can be regarded as the rotation shaft of the rotary foil trap 36. For example, an electric motor in which the rotation shaft 32 is directly connected to a rotor, or the like is used as the motor 40, but a speed changing mechanism such as a gear may be provided between the rotor and the rotation shaft 32, for example.

The rotary foil trap 36 is driven by the motor 40 to rotate. Thus, the plurality of rotating foils F collide with the debris DB coming from the plasma P to capture the debris DB. This makes it possible to inhibit the debris DB coming from the plasma P from entering the utilization apparatus 110.

The cooling mechanism cools the rotary foil trap, the rotation shaft 32, and the motor 40.

In this embodiment, a cooling mechanism that uses a refrigerant such as cooling water supplied from a water cooling pipe 41 is provided. A water inlet 42 to which cooling water is supplied from the water cooling pipe 41, and a water outlet 43 for returning the cooling water to the water cooling pipe 41 are provided outside the rotation drive portion 33. The water inlet 42 and the water outlet 43 are connected to the cooling mechanism. In addition, a coupler or the like is used for the connection of the water cooling pipe 41 and the water inlet 42 (water outlet 43). This facilitates the detachment of the water cooling pipe 41.

For example, the rotary foil trap 36 becomes hot due to the radiation from the plasma P. Hence, in order to prevent overheating of the rotary foil trap 36, a cooling mechanism that cools the rotation shaft 32 is provided. For example, as such a cooling mechanism, the rotation shaft 32 is made hollow to form a circulation passage for a refrigerant such as cooling water.

Passing cooling water supplied from the water cooling pipe 41 through this circulation passage makes it possible to cool the rotation shaft 32 and the rotary foil trap 36 connected thereto. In addition, since the motor 40 itself also generates heat during rotation, the heat can be removed by wrapping a pipe passing cooling water therethrough around the motor 40.

In such a manner, in the debris trap unit 30 according to this embodiment, the motor 40 is connected to the outside of the detachable member 31, the rotation shaft 32 passes through the detachable member 31, and the central support post 37 (rotary member) of the rotary foil trap is connected to the rotation shaft 32 inside the detachable member 31.

Such a configuration eliminates the need to arrange the rotation drive portion 33 on the inside of the chamber, thereby making it possible to downsize the connection chamber 15. In addition, the path of the EUV light from the plasma P to the output port 16 can be shortened, which makes it possible to suppress the spread of the beam diameter of the EUV light. As a result, it is possible to configure a compact optical system that is provided in the utilization apparatus 110.

FIG. 3 schematically shows a state in which the debris trap unit 30 is detached from the connection chamber 15 (chamber main body 1). When the debris trap unit 30 is detached, the operation of the EUV light source apparatus 100 is stopped, and then the inside of the connection chamber 15 is returned to an atmospheric pressure. Subsequently, the screws and the like that fix the detachable member 31 are removed, and the detachable member 31 is detached from the connection chamber 15. At that time, the rotary foil trap 36 is also detached together with the detachable member 31.

In such a manner, the debris trap unit 30 is configured such that the foil trap FT is unitized with the detachable member 31, which is a lid of the connection chamber 15 serving as the chamber main body 1, and can be detached from the side surface of the vacuum enclosure. Thus, it is possible to easily detach the foil trap FT disposed in the connection chamber 15, for example, without detaching the members constituting the light source section 2 (discharge electrodes EA and EB, containers CA and CB, etc.). In addition, since there is no need to disassemble the light source section 2, there is no need to adjust the optical axis of the EUV light, and the like. As a result, the operation time for maintenance can be satisfactorily shortened, and the operation rate of the EUV light source apparatus 100 can be improved.

### Configuration Example of Reinforced Connection Between Detachable Member and Rotation Drive Portion

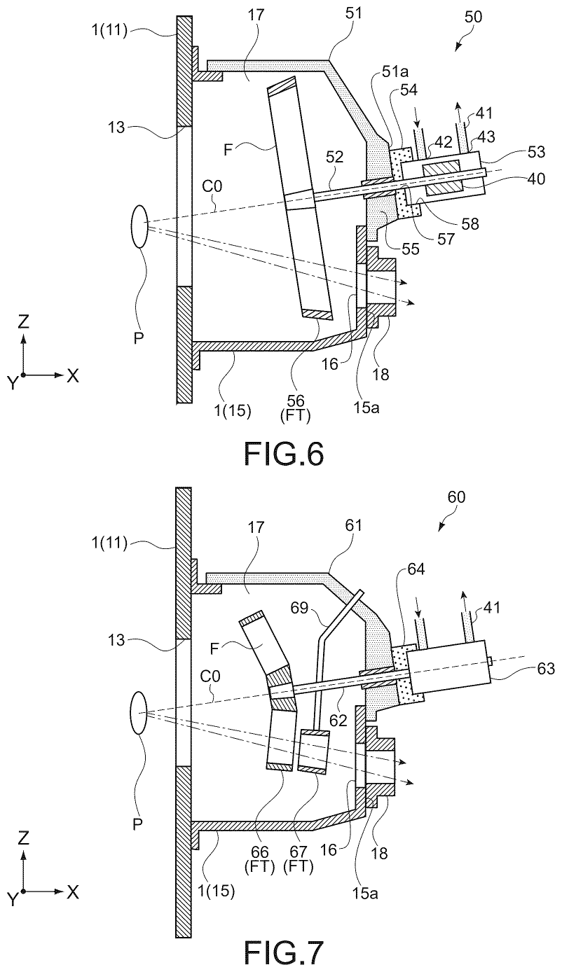

FIG. 6 is a schematic view showing another configuration example of the debris trap unit.

A debris trap unit 50 shown in FIG. 6 includes a detachable member 51, a rotary foil trap 56, a rotation shaft 52, a rotation drive portion 53, and a reinforcement member 54. The debris trap unit 50 is different from the debris trap unit 30 shown in FIGS. 2 and 3 in the configuration of the connection portion between the detachable member and the rotation drive portion. Note that in FIG. 6 the guide mechanism is omitted.

The detachable member 51 includes a reinforcement portion 55 that reinforces the rigidity of the portion to which the rotation drive portion 53 is connected. The reinforcement portion 55 is a structural part that reinforces the rigidity of the detachable member 51 itself, and is provided at the portion to which the rotation drive portion 53 is connected. In other words, it can be said that the reinforcement portion 55 is a structure that suppresses deformation or the like of the portion to which the load of the rotation drive portion 53 is applied.

In FIG. 6, a thick structure in which the thickness of the detachable member 51 is increased is provided as the reinforcement portion 55. Here, the central axis C0 of the rotary foil trap 56 (rotation shaft 52) is set inclined with respect to the horizontal plane. In this case, the rotation drive portion 53 is also disposed to be inclined with respect to the horizontal plane.

In such a case, an outer surface (connection surface 51a) of the detachable member 51 to which the rotation drive portion 53 is connected is configured as an inclined surface orthogonal to the central axis C0.

The connection surface 51a is set inclined in such a manner, so that the reinforcement portion 55 with an increased thickness is configured between the inner surface of the detachable member 51 and the connection surface 51a as shown in FIG. 6. Note that the structure of the reinforcement portion 55 is not limited, and for example, a rib structure may be provided to the inner surface of the detachable member 51 as the reinforcement portion 55.

Providing the reinforcement portion 55 directly below the connection surface 51a makes it possible to avoid a situation in which the detachable member 51 deforms due to the load applied from the rotation drive portion 53 to the connection surface 51a.

In addition, it is also possible to stably fix the rotation drive portion 53.

The reinforcement member 54 is a member that is configured as a separate member from the detachable member 51 and fixes the rotation drive portion 53 to the detachable member 51. The reinforcement member 54 is a structural member made of metal, for example, made of a material having higher rigidity than that of the detachable member 51. If the detachable member 51 is made of aluminum, for example, a reinforcement member 54 made of stainless steel is used. Note that the reinforcement member 54 and the detachable member 51 may be made of the same material.

The rotation drive portion 53 that controls the rotation of the rotation shaft 52 of the rotary foil trap 56 is connected to the rear of the rotation shaft 52. Inside the rotation drive portion 53, a cooling mechanism that circulates cooling water is provided to cool the heat of the rotation shaft 52, the rotary foil trap 56, or the like. Hence, in the rotation drive portion 53, a casing that houses the cooling mechanism is larger than the diameter of the rotation shaft 52. Therefore, fixing the casing of the rotation drive portion 53 makes it possible to more stably fix the rotation drive portion 53 as compared to the structure in which the rotation shaft 52 is received by a mechanical seal as shown in FIG. 2.

The reinforcement member 54 is disposed between the connection surface 51a of the detachable member 51 and the rotation drive portion 53 and functions as a seating to receive the rotation drive portion 53. The reinforcement member 54 includes a through-hole 57 to pass the rotation shaft 52 therethrough and a recessed portion 58 into which the casing of the rotation drive portion 53 can be fitted. The reinforcement member 54 is fixed to the connection surface 51a of the detachable member 51 by screwing or the like with the recessed portion 58 facing outward. In addition, the rotation drive portion 53 is fixed to the reinforcement member 54 by screwing or the like while being fitted into the recessed portion 58 of the reinforcement member 54.

In such a manner, in FIG. 6, the reinforcement member 54 is provided to be fixed to the detachable member 51 that is detachable from the connection chamber 15, and the rotation drive portion 53 supporting the rotation shaft 52 is fixed by being attached to the reinforcement member 54.

In such a manner, in FIG. 6, the reinforcement portion 55 provided in the detachable member 51 and the reinforcement member 54 configured separately from the detachable member 51 are used to reinforce the connection between the detachable member 51 and the rotation drive portion 53. Note that the configuration to reinforce the connection between the detachable member 51 and the rotation drive portion 53 is not limited. For example, either one of the reinforcement portion 55 of the detachable member 51 and the reinforcement member 54 may be provided.

For example, no reinforcement member 54 may be provided. In this case, the reinforcement portion 55 (thick structure or the like) including the inclined connection surface 51a is provided to the detachable member 51, and the rotation drive portion 53 is directly fixed to the connection surface 51a. Note that a recess or the like to receive the rotation drive portion 53 may be formed in the connection surface 51a. In addition, for example, no reinforcement portion 55 (thick structure or the like) of the detachable member 51 may be provided. In this case, the detachable member 51 is configured, for example, like the detachable member 31 shown in FIG. 2, and the connection surface 51a is a flat surface along the vertical direction. The reinforcement member 54 is configured to support the rotation drive portion 53 in the inclined state with respect to the connection surface 51a provided along the vertical direction in the manner described above.

For example, in the debris trap unit 50, the rotary foil trap 56 having a relatively large size of a diameter or width is mounted. FIG. 6 schematically shows the rotary foil trap 56 having a larger diameter than the rotary foil trap 56 shown in FIG. 2. When the size of the rotary foil trap 56 is large, the rotation drive portion 53 may be enlarged. In addition, the large size of the rotary foil trap 56 may increase vibration during rotation and shaking of the apparatus.

In contrast, in FIG. 6, the reinforcement member 54 to hold the casing of the rotation drive portion 53 is provided on the reinforcement portion 55 having a reinforced rigidity of the detachable member 51. Thus, the portion (casing of rotation drive portion 53) in which the cooling mechanism or the like for stably operating the rotary foil trap 56 is housed can be mechanically stably seated. As a result, even if a large-sized rotary foil trap 56 is used, vibration and shaking of the apparatus can be suppressed for stable operation.

Note that the configuration described with reference to FIG. 6 is also effective when using a relatively small-sized rotary foil trap.

### Configuration Example Including Fixed Foil Trap

FIG. 7 is a schematic view showing another configuration example of the debris trap unit. A debris trap unit 60 is provided with a fixed foil trap in addition to the rotary foil trap.

The debris trap unit 60 shown in FIG. 7 includes a detachable member 61, a rotary foil trap 66, a rotation shaft 62, a rotation drive portion 63, a reinforcement member 64, a fixed foil trap 67, and a gas introduction pipe 69. The detachable member 61, the rotation shaft 62, the rotation drive portion 63, and the reinforcement member 64 are configured to be similar to the detachable member 51, the rotation shaft 52, the rotation drive portion 53, and the reinforcement member 54 shown in FIG. 6. In addition, the rotary foil trap 36 shown in FIG. 2 is used as the rotary foil trap 66, but the rotary foil trap 56 having a relatively large size shown in FIG. 6 may also be used.

The fixed foil trap 67 is a foil trap FT to which a plurality of foils F are fixed.

The fixed foil trap 67 is provided between the rotary foil trap 66 and the output port 16 on the path of the EUV light travelling from the plasma P to the output port 16 of the connection chamber 15 (chamber main body 1). In other words, the fixed foil trap 67 is disposed on the downstream side of the rotary foil trap 66 and captures debris DB that has passed through the rotary foil trap 66.

In addition, the fixed foil trap 67 is disposed with reference to the central path on which a flux of light beams of the EUV light to be extracted from the output port 16 (EUV extracted light) passes. The central path is, for example, a path connecting the emission point of the plasma P and the center point of the output port 16. The fixed foil trap 67 is connected to the detachable member 61 via a holding portion, illustration of which is omitted, so as to intersect with the central path with the detachable member 61 being attached to the connection chamber 15. The specific configuration of the holding portion will be described later.

The gas introduction pipe 69 penetrates the detachable member 61 and introduces a transparent gas, which is transparent to EUV light, into the fixed foil trap 67. One end of the gas introduction pipe 69 is disposed to protrude from the outside of the detachable member 61 and is used as a gas introduction port. In addition, another end of the gas introduction pipe 69 is connected to the fixed foil trap 67. The transparent gas supplied to the fixed foil trap 67 is favorably a gas having high transmittance to the EUV light, and for example, a noble gas such as helium (He) or argon (Ar), or hydrogen (H₂) is used.

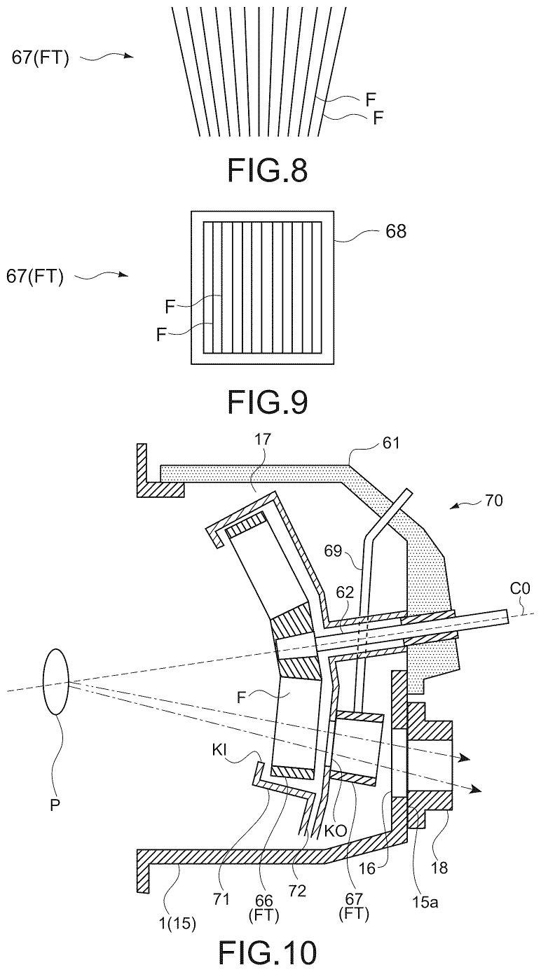

FIG. 8 is a schematic cross-sectional view showing a configuration example of the fixed foil trap. FIG. 9 is a schematic front view showing a configuration example of the fixed foil trap. FIG. 8 is a view of the fixed foil trap 67 taken along the central path of the EUV light. In addition, FIG. 9 is a view of the fixed foil trap 67 as viewed from the central path direction of the EUV light.

As shown in FIGS. 8 and 9, the fixed foil trap 67 includes a plurality of foils F and a fixed frame 68 that fixes the plurality of foils F. In this embodiment, the fixed frame 68 corresponds to a fixed member.

As shown in FIG. 9, the plurality of foils F are disposed at regular intervals as viewed from the central path direction of the EUV light. In addition, the fixed frame 68 has, for example, a rectangular shape as viewed from the front.

Note that the outer shape of the fixed frame 68 may be any shape. Furthermore, as shown in FIG. 8, the plurality of foils F are radially disposed to extend in the light beam direction of the EUV light in the cross section taken along the central path.

The plurality of foils F of the fixed foil trap 67 serve to divide the space, in which the fixed foil trap 67 is disposed, into finer portions, to reduce the conductance of those portions and locally increase the pressure.

In addition, the fixed foil trap 67 is supplied with a transparent gas via the gas introduction pipe 69. This makes it possible to increase the pressure in the fixed foil trap 67. In other words, in the connection chamber 15, the gas is localized in the fixed foil trap 67 to set a relatively high pressure portion.

The high-speed debris DB that has not been captured by the rotary foil trap 66 decreases its speed because the probability of collision with the gas increases in the region of the increased pressure in the fixed foil trap 67. In addition, the collision with the gas also changes the travelling direction of the debris DB. The fixed foil trap 67 captures the debris DB whose speed has been decreased and whose travelling direction has been changed in this manner by the foils For the fixed frame 68.

The rotary foil trap 66 and the fixed foil trap 67 are provided as described above, so that the debris DB can be satisfactorily captured. In addition, in the debris trap unit 60, both the rotary foil trap 66 and the fixed foil trap 67 are connected to the detachable member 61. This makes it possible to detach the rotary foil trap 66 as well as the fixed foil trap 67 by detaching the detachable member 61. Such a configuration makes it possible to shorten a maintenance time by replacing the debris trap unit 60 with a new one prepared in advance, for example.

### Foil Trap Cover

FIG. 10 is a schematic view showing a configuration example of a debris trap unit including a foil trap cover. A debris trap unit 70 shown in FIG. 10 has a configuration in which a foil trap cover 71 is provided to the debris trap unit 60 shown in FIG. 7. Note that in FIG. 7 the rotation drive portion and the utilization apparatus are omitted.

The foil trap cover 71 encloses the outer circumferential portion of the rotary foil trap 66 and collects debris DB scattered from the rotary foil trap 66. Providing the foil trap cover 71 makes it possible to prevent the debris DB captured by the rotary foil trap 66 from being scattered to the inside of the connection chamber 15.

The foil trap cover 71 includes an input-side opening KI and an output-side opening KO. The input-side opening KI is provided at a position at which the EUV light entering the rotary foil trap 66 is not blocked. The output-side opening KO is provided at a position at which the EUV light that has passed through the input-side opening KI and the rotary foil trap 66 to enter the fixed foil trap 67 is not blocked.

At least part of the debris DB captured by the rotary foil trap 66 moves radially on the foils F of the rotary foil trap 66 by centrifugal force, separates from the end portions of the foils F, and adheres to the inner surface of the foil trap cover 71. The foil trap cover 71 is heated by a heating means not shown in the figure (cover heating section) or by radiation accompanying EUV light emission. The debris DB that has adhered to the inner surface of the foil trap cover 71 is not solidified and remains in a liquid-phase state by the heating. The debris DB that has adhered to the inner surface of the foil trap cover 71 gathers at the lower part of the foil trap cover 71 due to the gravity, and is discharged from the lower part of the foil trap cover 71 to the outside of the foil trap cover 71 via a discharge pipe 72, to thereby become waste material. The debris DB that has become waste material is stored in a debris storage section not shown in the figure.

As shown in FIG. 10, in the debris trap unit 70, the foil trap cover 71 is connected to the detachable member 61. In other words, the foil trap cover 71 is unitized with the detachable member 61. For example, a tubular protrusion 73 is formed on the rear side of the foil trap cover 71 so as to surround the rotation shaft 62, and the tip of the protrusion 73 is connected to the detachable member 61. Of course, in addition to the protrusion 73, a portion connecting the foil trap cover 71 and the detachable member 61 may also be provided. This makes it possible to detach the foil trap cover 71 together with the detachable member 61.

In addition, in the example of FIG. 10, the fixed foil trap 67 is connected to the foil trap cover 71. Specifically, the fixed foil trap 67 is fixed to the rear side of the foil trap cover 71 so as to cover the output-side opening KO of the foil trap cover 71. Thus, use of the foil trap cover 71 makes it possible to easily unitize the fixed foil trap 67. In addition, there is no need to provide a special holding portion or the like for fixing the fixed foil trap 67, which can reduce the cost of the apparatus.

### Heat Shielding Member, Detection Sensor

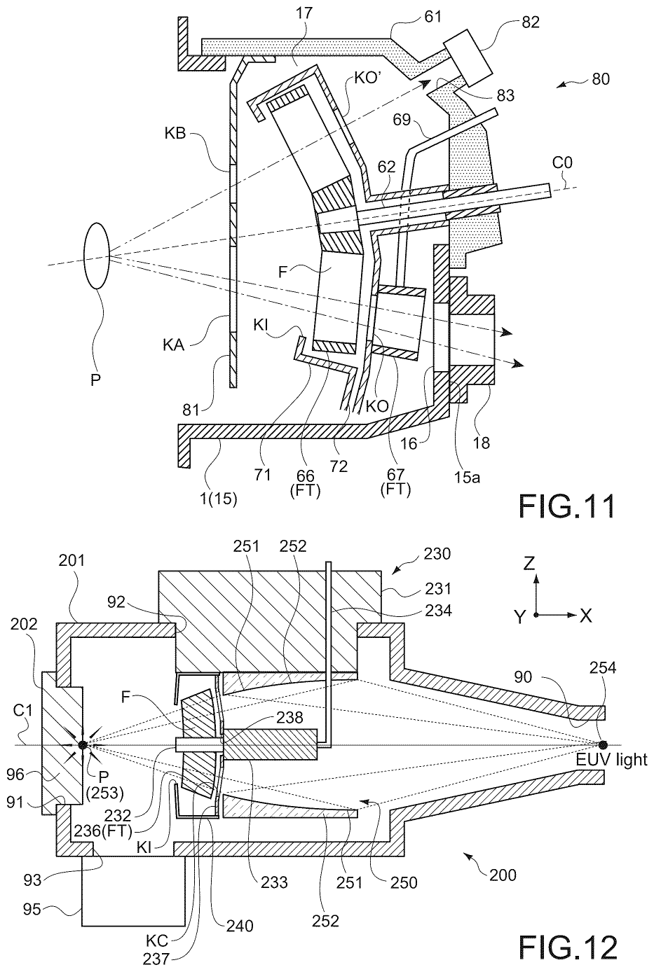

FIG. 11 is a schematic view showing a configuration example of a debris trap unit including a heat shielding plate. A debris trap unit 80 shown in FIG. 11 has a configuration in which a heat shielding member 81 and a detection sensor 82 are provided to the debris trap unit 70 shown in FIG. 10.

The heat shielding member 81 is connected to the detachable member 61 and disposed between the plasma P and the foil trap FT. In the example shown in FIG. 11, the heat shielding member 81 is disposed between the plasma P and the rotary foil trap FT. The heat shielding member 81 is disposed near the plasma P, and is thus made of, for example, a high-melting-point material such as molybdenum or tungsten. The heat shielding member 81 is provided, which can reduce radiation from the plasma P to the rotary foil trap 66 and can prevent overheating of the rotary foil trap 66.

The heat shielding member 81 is a plate-like member and is configured to cover the entire rotary foil trap FT. In addition, the heat shielding member 81 is provided with an opening KA and an opening KB for causing the EUV light from the plasma P to pass therethrough.

The opening KA is an opening to extract the EUV light to be emitted from the output port 16 towards the utilization apparatus 110. The opening KA is provided at an eccentric position from the rotation shaft (central axis C0) of the rotary foil trap 66. At that time, part of the EUV light emitted from the plasma P is extracted from the heat shielding member 81 via the opening KA at a predetermined three-dimensional angle, at an inclined angle with respect to the rotation shaft of the rotary foil trap 66. The rotary foil trap 66 and the fixed foil trap 67 are disposed such that the foils F are located on the central path of a flux of light beams of the EUV light (EUV extracted light) that has passed through the opening KA of the heat shielding member 81.

The opening KB is an opening to extract the EUV light emitted toward the detection sensor 82 to be described later. The opening KB is provided on a straight line from the emission point of the plasma P toward the detection sensor 82. In FIG. 11, the rotary foil trap 66 and the foil trap cover 71 are disposed between the plasma P and the detection sensor 82. Note that the foil trap cover 71 is provided with an output-side opening KO′ for causing the EUV light extracted via the opening KB to pass therethrough.

In FIG. 11, the upper end side of the heat shielding member 81 is bent and fixed to the inner surface of the detachable member 61. In other words, the heat shielding member 81 is unitized with the detachable member 61. This makes it possible to detach the heat shielding member 81 together with the detachable member 61 and to easily perform cleaning, replacement, and the like of the heat shielding member 81.

The detection sensor 82 is a sensor that is connected to the detachable member 61 and detects the state of the plasma P. In this embodiment, the detachable member 61 is provided with a through-hole 83 for connecting the detection sensor 82. The detection sensor 82 is connected to the outside of the detachable member 61 so as to close the through-hole 83.

The EUV light that has passed through the opening KB of the heat shielding member 81 described above, the rotary foil trap 66, the output-side opening KO′ of the foil trap cover 71, and the through-hole 83 of the detachable member 61 enters the detection sensor 82. Note that the detection sensor 82 may be connected to the inside of the detachable member 61 without providing the through-hole 83.

For example, an optical sensor or the like that detects EUV light is used as the detection sensor 82. In this case, EUV light intensity (emission intensity of plasma P) can be detected by the detection sensor 82. In addition, for example, a camera sensor or the like that images a state of the plasma P may be used as the detection sensor 82. In this case, the emission state of the plasma P can be observed by the detection sensor 82. Additionally, the type of detection sensor 82 is not limited, and any sensor capable of detecting a state of the plasma P (temperature, color, size, etc.) can be used.

In such a manner, the detection sensor 82 is connected to the detachable member 61 in FIG. 11. In other words, the detection sensor 82 is unitized with the detachable member 61. This makes it possible to detach the detection sensor 82 together with the detachable member 61 and to easily perform cleaning, replacement, and the like of the detection sensor 82.

As described above, in the debris trap units 30, 50, 60, 70, and 80 according to this embodiment, at least one foil trap FT including a plurality of foils F that capture debris from plasma P is connected to a detachable member that covers the opening 17 of the connection chamber 15 serving as the chamber main body 1 and is attached/detached to/from the connection chamber 15. In the attached state of the detachable member, the plurality of foils F are disposed on the path of the radiation from the plasma P to the output port. In addition, when the detachable member is detached, the foil trap FT can also be detached together. This makes it possible to shorten a maintenance time for the foil trap FT, thereby making maintenance more efficient.

In general, a light source apparatus that emits EUV light is connected to a utilization apparatus for using the EUV light. The utilization apparatus is provided with a complex optical system to adjust the EUV light emitted from the light source apparatus, and its optical axis is adjusted starting from the emission point of the plasma P. In addition, the utilization apparatus is often a larger apparatus than the light source apparatus, and it is also conceivable that the utilization apparatus may be coupled to another apparatus. Since the light source apparatus is located at the end of the system, it has been necessary to disassemble the light source apparatus once for maintenance of the debris trap.

In addition, in the disassembly of the light source apparatus as well, the members such as the lid of the chamber, the rotary electrodes, the raw material containers, and the plate at the boundary with the debris trap (heat shielding plate etc.) are required to be detached one by one from the end, and then the debris trap can be finally detached. Hence, when the maintenance of the debris trap is performed, it has taken a considerable labor and time to touch the debris trap itself.

In addition, as described above, the optical system of the utilization apparatus is adjusted to the optical axis starting from the emission point of the plasma P. On the other hand, in the maintenance to disassemble the light source apparatus, the rotary electrode serving as the emission point is detached. Hence, after the maintenance of the debris trap is finished and the light source apparatus is assembled again, the adjustment to align the optical axes is further required. As a result, there has been a possibility that the downtime of the light source apparatus and the utilization apparatus is extended, and the utilization efficiency of the apparatuses is reduced.

In the debris trap unit according to this embodiment, the foil trap FT is connected to the detachable member attached to the opening 17 of the connection chamber 15 serving as the chamber main body 1. In other words, a lid (detachable member) is provided to a part of the container (connection chamber 15) that houses the foil trap FT, and the lid and the foil trap FT are unitized.

In such a configuration, when the foil trap FT is detached, the detachable member only needs to be detached from the connection chamber 15, and it is unnecessary to disassemble the light source section 2 and the like. This makes it possible to easily attach or detach the foil trap FT. In addition, it is possible to significantly shorten the time required for maintenance of the foil trap FT.

In addition, in this embodiment, the members unitized with the debris trap unit do not include an optical element that changes the optical path of the EUV light. This makes it possible to perform maintenance in a state in which the optical axis reaching the optical system of the utilization apparatus 110 from the emission point (light generating location) of the plasma P is substantially maintained. Thus, there is no need for drastic adjustment of the optical axis, which is required when, for example, the discharge electrode is detached, and it is possible to adjust the optical axis relatively easily. As a result, the downtime of the light source apparatus and the utilization apparatus is shortened, and the utilization efficiency of the apparatuses can be improved.

In addition, the rotary foil trap, the fixed foil trap, the foil trap cover, the heat shielding member, the detection sensor, and the like can be integrally unitized in the debris trap unit. This makes it possible to perform maintenance of the plurality of unitized members at the same time, and to save the time and effort for the maintenance. This makes it possible to efficiently perform maintenance of various members provided in the connection chamber 15.

### Second Embodiment

An EUV light source apparatus according to a second embodiment of the present invention will be described. In the following description, the description will be omitted or simplified for the parts similar to the configurations and actions in the EUV light source apparatus 100 described in the above embodiment.

FIG. 12 is a schematic cross-sectional view showing a configuration example of an EUV light source apparatus including a debris trap unit according to a second embodiment. An EUV light source apparatus 200 includes a chamber main body 201, a light source unit 202, and a debris trap unit 230. In this embodiment, a configuration in which a condensing mirror 250 that condenses EUV light is unitized with the debris trap unit 230 will be described.

The chamber main body 201 includes an output port 90 for EUV light, a first opening 91, a second opening 92, and a vacuum discharge port 93. The chamber main body 201 shown in FIG. 12 has a structure in which a cone-shaped casing is connected to an end of a tubular casing.

The output port 90 is provided to the tip of the cone-shaped casing. In addition, the first opening 91 is provided at the end portion of the tubular casing, on the side opposite to the output port 90. In addition, the second opening 92 and the vacuum discharge port 93 are provided to the side surface of the tubular casing.

The output port 90 is an optical window for introducing EUV light from plasma P to a utilization apparatus not shown in the figure. The output port 90 is typically a through-hole, but a transparent member such as an optical filter may be provided.

The first opening 91 is an opening to which the light source unit 202 is connected.

The second opening 92 is an opening to which the debris trap unit 230 is connected. In FIG. 12, the second opening 92 is formed on the upper side in the figure.

The vacuum discharge port 93 is connected to a vacuum pump 95 that exhausts the chamber main body 201. In FIG. 12, the vacuum discharge port 93 is formed on the lower side in the figure.

The light source unit 202 is obtained by unitizing a mechanism for generating plasma P with a base 96 functioning as a lid of the first opening 91.

The light source unit 202 is configured as an apparatus that generates plasma P by the LDP method, for example, similarly to FIG. 1. In this case, a pair of discharge electrodes disposed to face each other and a pair of containers that supply a plasma raw material to the respective discharge electrodes are fixed to the base 96. In addition, a transparent window not shown in the figure is provided to the chamber main body 201 so as to introduce an energy beam (e.g., laser beam).

The energy beam is applied to one discharge electrode in a discharge region in which the discharge electrodes face each other. By the irradiation of the energy beam, a gas-phase plasma raw material is supplied to the discharge region.

When power is supplied to each of the discharge electrodes, the plasma raw material is heated and excited by discharge, and plasma P is generated.

Note that a light source unit 202 that generates plasma P by another method such as the LPP method may be used instead of the light source unit 202 of the LDP method.

The debris trap unit 230 shown in FIG. 12 is obtained by unitizing a foil trap FT and the condensing mirror 250. The debris trap unit 230 includes a detachable member 231, a rotary foil trap 236 as a foil trap FT, a rotation shaft 232, a rotation drive portion 233, a water cooling pipe 234, an RFT supporting portion 237, a foil trap cover 240, and the condensing mirror 250.

The detachable member 231 is a member that covers the second opening 92 and is configured to be attachable/detachable to/from the chamber main body 201, and functions as a lid to close the second opening 92. The rotary foil trap 236, the condensing mirror 250, and the like constituting the debris trap unit 230 are directly or indirectly connected to the detachable member 231 to be unitized.

In the example of FIG. 12, with the detachable member 231 being connected to the chamber main body 201, the rotary foil trap 236 and the condensing mirror 250 are disposed in the stated order on the path from the emission point of the plasma P toward the output port 90.

The rotary foil trap 236 includes a plurality of foils F radially disposed, and is connected to the rotation drive portion 233 via the rotation shaft 232. The water cooling pipe 234 that penetrates the detachable member 231 is connected to the rotation drive portion 233, and cooling water or the like is supplied thereto. In addition, a power cable or the like is wired for the rotation drive portion 233 as appropriate. In this embodiment, with the debris trap unit 230 being attached to the chamber main body 201, the rotary foil trap 236 and its drive mechanism (rotation shaft 232 and rotation drive portion 233) are all housed in the chamber main body 201.

The RFT supporting portion 237 is a member that is fixed to the detachable member 231 and supports the RFT (rotary foil trap 236) with respect to the detachable member 231. Specifically, the RFT supporting portion 237 is configured to support the rotation drive portion 233. In addition, the rotation shaft 232 connected to the rotary foil trap 236 is rotatably supported via a bearing mechanism such as a bearing not shown in the figure, which is built in the rotation drive portion 233. In such a manner, the RFT supporting portion 237 supports the rotary foil trap 236 via the rotation drive portion 233 and the rotation shaft 232.

As shown in FIG. 12, the RFT supporting portion 237 is, for example, a plate-like member as a whole, and includes a through-hole 238 for passing the rotation shaft 232 therethrough, and an opening KC for passing EUV light therethrough.

In addition, the RFT supporting portion 237 is disposed between the rotary foil trap 236 and the rotation drive portion 233, and an end surface of the rotation drive portion 233 on the front side is fixed to the RFT supporting portion 237. At that time, the RFT supporting portion 237 and the rotation drive portion 233 are fixed to each other such that the axis of the rotation shaft 232 is aligned with the central axis C1 of the condensing mirror 250 to be described later.

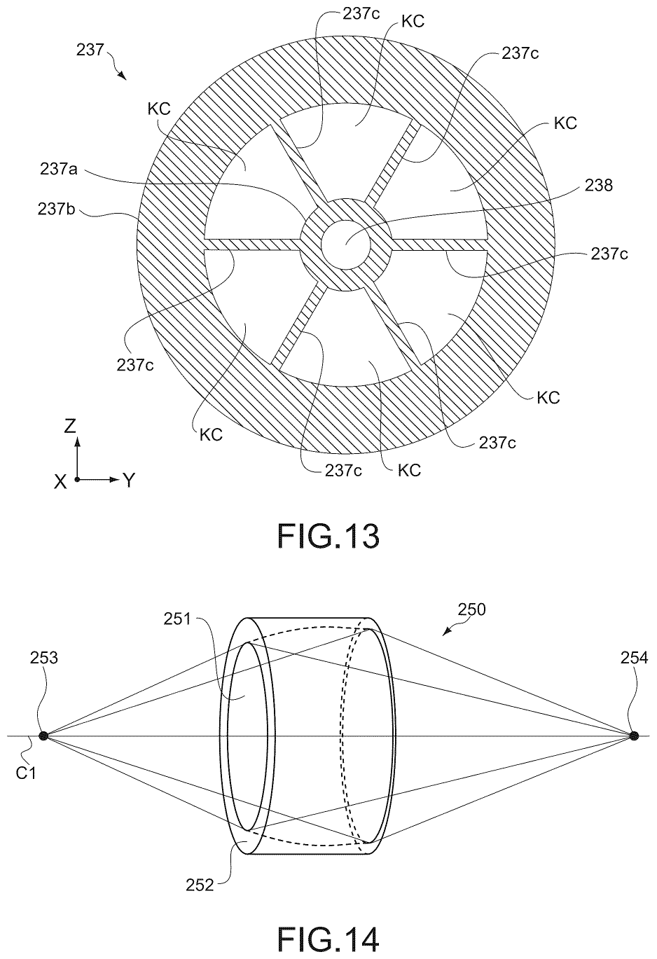

FIG. 13 is a schematic plan view showing a configuration example of the RFT supporting portion 237. The RFT supporting portion 237 includes a center portion 237a, a circumferential portion 237b, and a plurality of spokes 237c.

The center portion 237a is a portion provided at the center of the RFT supporting portion 237 and a portion to which the rotation drive portion 233 is fixed. The center portion 237a is provided with a through-hole 238 having a larger inner diameter than the diameter of the rotation shaft 232. The circumferential portion 237b is provided so as to surround the center portion 237a at a certain distance from the center portion 237a. The circumferential portion 237b is, for example, a portion connected to the detachable member 231 or the foil trap cover 240. The plurality of spokes 237c are long members that connect the center portion 237a and the circumferential portion 237b to each other. A cavity surrounded by the center portion 237a, the circumferential portion 237b, and each spoke 237c is the opening KC for passing the EUV light therethrough.

In the example shown in FIG. 13, six spokes 237 c are disposed at intervals of the angle of 60 degrees, and six openings KC are configured between the center portion 237a and the circumferential portion 237b. Those openings KC are mainly provided on the optical path of the EUV light that has passed through the rotary foil trap 236.

Additionally, the number of spokes 237c and openings KC and the shapes thereof are not limited.

In addition, in the example shown in FIG. 13, the outer circumference of the RFT supporting portion 237 (circumferential portion 237b) is a cylindrical surface, but for example, in order to be fixed to the detachable member 231, the outer circumference may be partially flat.

Referring back to FIG. 12, the foil trap cover 240 encloses the outer circumferential portion of the rotary foil trap 236 and collects the debris DB scattered from the rotary foil trap 236. The foil trap cover 240 is a tubular member that houses the rotary foil trap 236. An input-side opening KI to which the EUV light enters is provided on the front side of the foil trap cover 240 (on the side facing the plasma P), and the RFT supporting portion 237 is connected to the rear side of the foil trap cover 240. In the example shown in FIG. 12, the RFT supporting portion 237 covers the rear side of the foil trap cover 240 and functions as a part of the cover.

For example, the RFT supporting portion 237 and the foil trap cover 240 are each fixed to the detachable member 231 while being attached to each other. Alternatively, for example, one of the RFT supporting portion 237 or the foil trap cover 240 may be fixed to the detachable member 231, and the other one may be fixed to the one attached to the detachable member 231. Alternatively, the RFT supporting portion 237 and the foil trap cover 240 may not be attached to each other and may be individually fixed to the detachable member 231. In any case, the rotation drive portion 233 is supported by the RFT supporting portion 237.

Note that, in addition to the RFT supporting portion 237, the water cooling pipe 234 connected to the rear of the rotation drive portion 233 may be configured as a member that supports the rotation drive portion 233. In addition, the water cooling pipe 234 may be disposed along the RFT supporting portion 237 and may be connected to the front of the rotation drive portion 233.

FIG. 14 is a schematic perspective view showing a configuration example of the condensing mirror.

The condensing mirror 250 is connected to the detachable member 231 and condenses the EUV light from the plasma P.

The condensing mirror 250 includes a reflective surface 251 that reflects the EUV light, and a support 252 to which the reflective surface 251 is provided.

In this embodiment, the reflective surface 251 is formed on an inner circumferential surface of the tubular support 252. Therefore, the condensing mirror 250 is a tubular reflective mirror. As shown in FIG. 14, the condensing mirror 250 is a grazing-incidence mirror, and the reflective surface 251 is formed of a single-layer film. For example, the reflective surface 251 is formed by coating the inner circumferential surface of the support 252 with a single-layer film of ruthenium.

In the following, the side where the EUV light enters will be described as the front of the condensing mirror 250, and the side where the EUV light exits will be described as the rear of the condensing mirror 250.

The reflective surface 251 is, for example, a curved surface that is rotationally symmetrical about the central axis C1. The shape of the reflective surface 251 (the shape of the inner circumferential surface of the support 252) is designed to condense the light from an emission point 253 on the central axis C1, which is set in front of the condensing mirror 250, to a focal point 254 on the central axis C1, which is set at the rear of the condensing mirror. Here, the emission point 253 of the condensing mirror 250 corresponds to the emission point of the plasma P. In addition, the focal point 254 of the condensing mirror 250 corresponds to, for example, the center position of the output port 90.

Note that the reflective surface 251 is not limited to the rotationally symmetric configuration, and a free-form surface or the like that is designed by optical simulation may also be used.

As shown in FIG. 12, the support 252 of the condensing mirror 250 is fixed to the detachable member 231 such that the emission point of the plasma P and the emission point 253 set for the condensing mirror 250 are aligned with each other and that the center position of the output port 90 and the focal point 254 set for the condensing mirror 250 are aligned with each other, with the detachable member 231 being connected to the chamber main body 201. Thus, the EUV light that has been emitted from the plasma P, has passed through the rotary foil trap 236, and has entered the front of the condensing mirror 250 is condensed at the output port 90.

In addition, the condensing mirror 250 is unitized with the rotary foil trap 236, which makes it possible to detach the condensing mirror 250 together with the detachable member 231. This makes it possible to easily perform cleaning, replacement, and the like of the condensing mirror 250.

In addition, the rotary foil trap 236 that is the foil trap FT is disposed between the plasma P and the condensing mirror 250. This makes it possible to capture debris DB dissipated from the plasma P before it enters the condensing mirror 250, thereby preventing the debris DB from colliding with the reflective surface 251 and being deposited thereon. In addition, when the detachable member 231 is detached, the rotary foil trap 236 is also detached, thereby allowing easy maintenance of the rotary foil trap 236.

Note that the condensing mirror 250 is not connected to the RFT supporting portion 237 and the foil trap cover 240, and is fixed to the detachable member 231 independently of the RFT supporting portion 237 and the foil trap cover 240. Thus, for example, a situation in which the vibration generated by rotation of the rotary foil trap 236 is directly transmitted to the condensing mirror 250 can be avoided. This makes it possible to suppress vibration of the condensing mirror 250.

In addition, in this configuration using the tubular condensing mirror 250, the EUV light that has passed through the entire circumference of the rotary foil trap 236 is condensed. This makes it possible to increase the amount of EUV light as compared to the case where only the EUV light passing through part of the angle range of the rotary foil trap is extracted, for example, as described with reference to FIG. 2 and the like.

Note that the reflective surface 251 is a single layer in FIGS. 12 and 14, but a reflective surface 251 of a plurality of layers may be configured so as to surround the central axis C1, for example. This can further improve the light-condensing efficiency of the EUV light.

### Rotary Foil Trap and Fixed Foil Trap

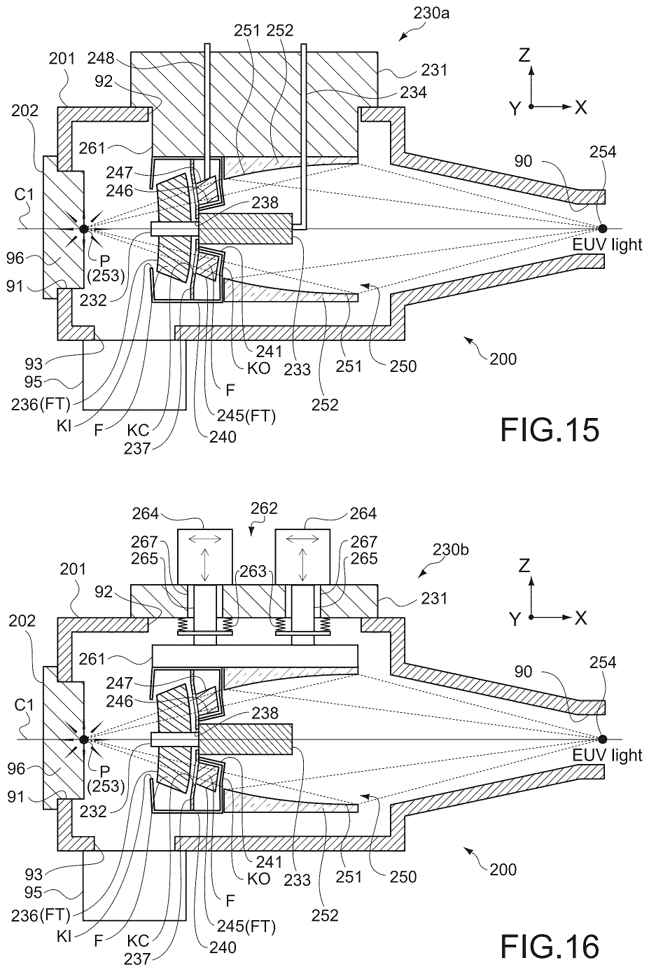

FIG. 15 is a schematic view showing another configuration example of the debris trap unit including the condensing mirror. A debris trap unit 230a shown in FIG. 15 is obtained by unitizing two types of foil traps FT (rotary foil trap 236 and fixed foil trap 245) with the condensing mirror 250. The debris trap unit 230a has a configuration in which the fixed foil trap 245 is added to the debris trap unit 230 shown in FIG. 12.

The fixed foil trap 245 includes an inner ring 246 disposed around a predetermined axis, and an outer ring 247 disposed to surround the inner ring 246. In the tubular inner region sandwiched between the inner ring 246 and the outer ring 247, a plurality of foils F are radially disposed around the predetermined axis. At that time, each foil F is on a plane including the predetermined axis. In such a manner, the tubular fixed foil trap 245 is used in this embodiment.

The fixed foil trap 245 is disposed on the rear of the rotary foil trap 236 with the RFT supporting portion 237 being sandwiched therebetween such that the predetermined axis and the axis of the rotation shaft 232 are aligned with each other. In addition, the inner ring 246 and the outer ring 247 of the fixed foil trap 245 are configured so as not to block the optical path of the EUV light emitted from the opening KC disposed in the RFT supporting portion 237. In addition, a gas introduction pipe 248 that penetrates the detachable member 231 is connected to the inner region of the fixed foil trap 245, and a transparent gas having high transmittance to the EUV light is supplied.

For example, the high-speed debris DB that has not been captured by the rotary foil trap 236 collides with the gas in the region of the increased pressure in the fixed foil trap 245. The debris DB whose speed has been decreased and whose travelling direction has been changed by the collision with the gas is captured by the foils F, the inner ring 246, and the outer ring 247.

The rotary foil trap 236 and the fixed foil trap 245 are provided in such a manner, so that the debris DB can be satisfactorily captured.

The foil trap cover 240 provided to the debris trap unit 230a encloses both the rotary foil trap 236 and the fixed foil trap 245. In other words, the rotary foil trap 236 and the fixed foil trap 245 disposed with the RFT supporting portion 237 being sandwiched therebetween are housed in the foil trap cover 240.

Similarly to FIG. 12, an input-side opening KI to which the EUV light enters is provided on the front side of the foil trap cover 240. In addition, an insertion hole 241 surrounded by an annular protrusion that protrudes toward the RFT supporting portion 237 is formed on the rear side of the foil trap cover 240. The insertion hole 241 is a hole in which the rotation shaft 232 and the rotation drive portion 233 are disposed, and the tip of the insertion hole 241 (protrusion) is connected to the RFT supporting portion 237. In addition, an output-side opening KO from which the EUV light that has passed through the fixed foil trap 245 exits is provided around the insertion hole 241.

For example, the debris DB captured by the fixed foil trap 245 flows into the foil trap cover 240 and is collected by the foil trap cover 240. This makes it possible to avoid a situation in which the debris DB captured by the fixed foil trap 245 adheres to the rotation shaft 232 or the like.

In the example shown in FIG. 15, the fixed foil trap 245 is fixed to the RFT supporting portion 237, but the fixed foil trap 245 may be fixed to the foil trap cover 240, for example.

In addition, the RFT supporting portion 237 and the foil trap cover 240 may be fixed to the detachable member 231 while being attached to each other, or one of them may be attached to the other one fixed to the detachable member 231. In addition, the RFT supporting portion 237 and the foil trap cover 240 may be individually fixed to the detachable member 231.

Note that the condensing mirror 250 is not connected to the foil trap cover 240, but is fixed to the detachable member 231 independently of the foil trap cover 240. Thus, vibration from the rotary foil trap 236 is less likely to be transmitted to the condensing mirror 250.

### Position Adjustment Mechanism

FIG. 16 is a schematic view showing another configuration example of the debris trap unit including the condensing mirror. A debris trap unit 230b shown in FIG. 16 has a configuration in which the debris trap unit 230a shown in FIG. 15 is provided with a position adjustment mechanism 262.

The debris trap unit 230b includes an intermediate member 261, a position adjustment mechanism 262, and an extensible cover 263. Note that the illustration of the water cooling pipe and the gas supply pipe described with reference to FIGS. 12 and 15 is omitted in FIG. 16.

The intermediate member 261 is configured as a member independent of the detachable member 231, and integrally supports the rotary foil trap 236, the fixed foil trap 245, and the condensing mirror 250. Specifically, the rotary foil trap 236 and the fixed foil trap 245 are fixed to the intermediate member 261 via at least one of the RFT supporting portion 237 or the foil trap cover 240. In addition, the support 252 of the condensing mirror 250 is fixed to the intermediate member 261 independently of the RFT supporting portion 237 and the foil trap cover 240.

The position adjustment mechanism 262 is a mechanism for adjusting the arrangement of the condensing mirror 250. Here, the arrangement of the condensing mirror 250 includes the position and posture of the condensing mirror 250. The position of the condensing mirror 250 is, for example, an X-coordinate, a Y-coordinate, and a Z-coordinate of the reference position (e.g., position of the center of gravity) of the condensing mirror 250. In addition, the posture of the condensing mirror 250 is a roll angle, a pitch angle, and a yaw angle of the condensing mirror 250. Note that if the condensing mirror 250 is rotationally symmetric, the roll angle does not need to be adjusted.

The position adjustment mechanism 262 is configured to be capable of adjusting those parameters.

The position adjustment mechanism 262 includes a drive section 264 and an adjustment shaft 265.

The drive section 264 is connected to the adjustment shaft 265 and drives the adjustment shaft 265. The drive section 264 is configured, for example, such that the position of the adjustment shaft 265 can be adjusted in the three axial directions orthogonal to each other.

In addition, the drive section 264 may be configured, for example, such that the posture, such as rotation or inclination, of the adjustment shaft 265 can be adjusted. As the drive section 264, a servo motor or the like is used, but a mechanism or the like that manually adjusts the position or posture of the adjustment shaft 265 may be used, for example.

In FIG. 16, two pairs of the drive section 264 and the adjustment shaft 265 are disposed, but the necessary number of drive sections 264 and adjustment shafts 265 may be disposed such that the arrangement of the condensing mirror 250 can be adjusted.

In addition, the drive section 264 is connected to the outside of the detachable member 231, and the adjustment shaft 265 is connected to the intermediate member 261, inside the detachable member 231, through a through-hole 267 provided to the detachable member 231. This configuration makes it possible to use, for example, a servo motor or the like that operates in atmosphere, as the drive section 264 as it is and to suppress the cost of the apparatus.

Note that the through-hole 267 for passing the adjustment shaft 265 therethrough is formed to be larger than the adjustment shaft 265 such that the position or posture of the adjustment shaft 265 can be changed. In this regard, the adjustment shaft 265 is provided with the extensible cover 263 so as to close the clearance between the through-hole 267 and the adjustment shaft 265.

The extensible cover 263 is a tubular member with an open end. The side surface of the extensible cover 263 is configured using bellows, for example. The open end of the extensible cover 263 is connected to the inside of the detachable member 231 so as to surround the through-hole 267 through which the adjustment shaft 265 passes. In addition, the adjustment shaft 265 penetrates the bottom portion of the extensible cover 263 to be connected to the intermediate member 261. Note that the extensible cover 263 is connected to the detachable member 231 and the adjustment shaft 265 without leakage. This makes it possible to adjust the arrangement of the condensing mirror 250 by moving the adjustment shaft 265 while maintaining the reduced-pressure atmosphere of the chamber main body 201.

The condensing mirror 250 is an optical element that adjusts the optical path of the EUV light. Hence, for example, if the position or posture of the condensing mirror 250 shifts when the debris trap unit 230b is attached/detached, the optical path of the EUV light from the light source unit 202 to the utilization apparatus may change, and the focal point or the like may shift.

In such a case as well, in the debris trap unit 230b, the position or posture of the condensing mirror 250 can be adjusted using the position adjustment mechanism 262. This makes it possible to easily adjust the optical path of the EUV light, or the like, and complete maintenance in a short time even when the condensing mirror 250 is unitized.

Note that in FIG. 16 the drive section 264 of the position adjustment mechanism 262 is disposed outside the detachable member 231. The drive section 264 is not limited to this, and may be disposed inside the detachable member 231.

In this case, there is no need to provide the through-hole 267 for passing the adjustment shaft 265 therethrough, the extensible cover 263 for preventing leakage, and the like in the detachable member 231, so that the configuration of the apparatus can be simplified.

### Vibration-Isolation Mechanism

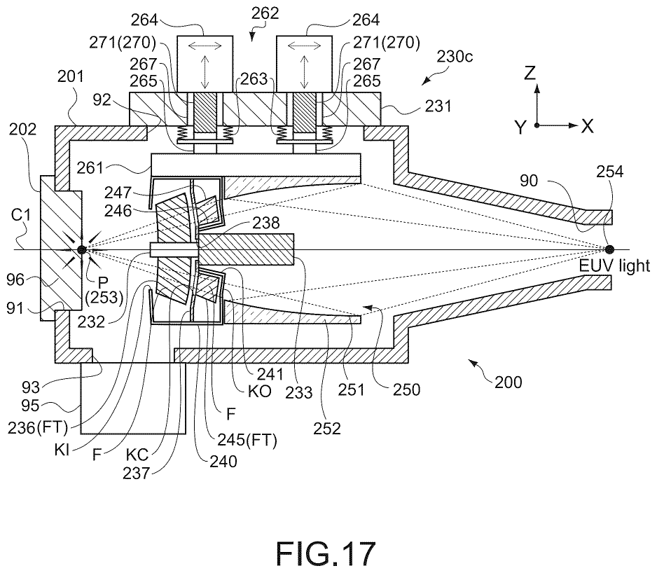

FIG. 17 is a schematic view showing another configuration example of the debris trap unit including the condensing mirror. A debris trap unit 230c shown in FIG. 17 has a configuration in which a vibration-isolation mechanism 270 is provided to the debris trap unit 230b shown in FIG. 16.

The vibration-isolation mechanism 270 is a mechanism that suppresses vibration transmitted to the chamber main body 201. In other words, the vibration-isolation mechanism 270 prevents vibration of the debris trap unit 230c including the condensing mirror 250 from being transmitted to the chamber main body 201. The vibration transmitted to the chamber main body 201 is mainly vibration generated when the rotary foil trap 236 provided to the debris trap unit 230c and its drive mechanism (rotation shaft 232 and rotation drive portion 233) operate. The light source unit 202 that generates plasma P is connected to the chamber main body 201. Hence, when the chamber main body 201 vibrates, the light may be seen shifting the position in the utilization apparatus located downstream of the focal point 254. In addition, the vibration itself may be transmitted to the utilization apparatus and cause a problem. The vibration-isolation mechanism 270 is a mechanism for making it difficult to transmit such vibration to the chamber main body 201 and for reducing the vibration of the debris trap unit 230c itself.

The vibration-isolation mechanism 270 is a mechanism that includes a vibration-isolation section 271 and a vibration sensor (illustration of which is omitted) and performs active vibration isolation by operating the vibration-isolation section 271 in response to the output of the vibration sensor.

The vibration-isolation section 271 is an element that expands and contracts to reduce vibration, and for example, a linear actuator formed of a piezoelectric element or a stepping motor is used. In the example shown in FIG. 17, the vibration-isolation section 271 is provided for each pair of the drive section 264 and the adjustment shaft 265. Specifically, the vibration-isolation section 271 is provided between the drive section 264 and the adjustment shaft 265. In other words, it can be said that the vibration-isolation section 271 functions as part of the adjustment shaft 265.

The vibration sensor is a sensor that detects the vibration generated by the operation of the rotary foil trap 236, and is configured to, for example, detect the vibration of the intermediate member 261. For example, a laser displacement meter, an acceleration sensor, or the like is used as the vibration sensor.

The vibration-isolation section 271 expands and contracts to cancel out the vibration of the intermediate member 261 on the basis of the output of the vibration sensor. The expansion and contraction of the vibration-isolation section 271 suppresses the vibration of the intermediate member 261, which is generated by the operation of the rotary foil trap 236 or the like, and as a result, suppresses the vibration transmitted from the intermediate member 261 to the chamber main body 201. This makes it possible to suppress positional fluctuations of light or the like in the utilization apparatus to which the EUV light is to be supplied. In addition, vibration transmitted from the chamber main body 201 to the utilization apparatus is also suppressed, thereby avoiding the occurrence of defects due to the vibration. In addition, since the vibration of the intermediate member 261 is suppressed, the vibration of the condensing mirror 250 fixed to the intermediate member 261 is suppressed. This makes it possible to prevent deterioration of the EUV light condensing accuracy by the condensing mirror 250.

In the example shown in FIG. 17, the vibration-isolation section 271 is provided between the drive section 264 and the adjustment shaft 265. This makes it possible to introduce, for example, a linear actuator with a relatively large extension/contraction length, which can provide sufficient vibration-isolation performance. Note that the vibration-isolation section 271 may be provided at another location.

For example, the vibration-isolation section 271 may be provided between the intermediate member 261 and the fixed member (RFT supporting portion 237 or foil trap cover 240) of the rotary foil trap 236.

Alternatively, the vibration-isolation section 271 may be provided between the intermediate member 261 and the condensing mirror 250. In other words, the vibration-isolation mechanism 270 may be configured to suppress vibration transmitted to the condensing mirror 250.

Thus, for example, the EUV light condensing accuracy can be kept at a high level.

In addition, the vibration-isolation mechanism 270 may be configured to allow passive vibration isolation. In this case, a member or the like that functions as a damper to attenuate vibration is used for the vibration-isolation section 271. In the passive vibration isolation, for example, the vibration-isolation section 271 can be inexpensively configured, and there is no need to provide a vibration sensor or the like. Therefore, the cost of the apparatus can be reduced.

In FIG. 17, the configuration in which the vibration-isolation mechanism 270 is provided to the debris trap unit 230c including the position adjustment mechanism 262 has been described. The present invention is not limited to this, but the vibration-isolation mechanism 270 may be provided to a debris trap unit without the position adjustment mechanism 262, for example, as shown in FIGS. 12 and 15. In this case, for example, the vibration-isolation section 271 is provided between the detachable member 231 and the fixed member (RFT supporting portion 237 or foil trap cover 240) of the rotary foil trap 236. Alternatively, the vibration-isolation section 271 may be provided between the detachable member 231 and the condensing mirror 250.

In the configuration in which the condensing mirror 250 is unitized in such a manner, providing the vibration-isolation mechanism 270 makes it possible to suppress vibration transmitted to the chamber main body 201 and/or the condensing mirror 250 (such as vibration generated by the operation of the rotary foil trap 236). This makes it possible to supply the properly condensed EUV light to the utilization apparatus.

### Other Embodiments

The present invention is not limited to the embodiments described above, and various other embodiments can be achieved.

In the embodiments described above, the EUV light source apparatus that extracts EUV light from plasma P has been described. The present invention is not limited to this, but may be applied to a light source apparatus that extracts X-rays and the like, which have shorter wavelengths than EUV light, from the plasma P.

In addition, in the embodiments described above, the light source apparatus of the LDP method has been mainly described, but the method for generating EUV light or radiation such as X-rays is not limited. For example, the present invention may be applied to a light source apparatus of the LPP method. Additionally, if debris DB from plasma P is captured in any apparatus that generates plasma P, the efficiency of maintenance of a foil trap can be improved by applying the debris trap unit according to the present invention.

In the present disclosure, words such as “substantially” and “approximately” are suitably used to readily understand the explanation, but there is no clear difference between the cases in which these words are used and the cases in which they are not used.

In other words, in the present disclosure, concepts that define shape, size, position relationship, state, and the like, such as “center”, “equal”, “same”, “orthogonal”, “parallel”, “symmetrical”, and “cylindrical”, are concepts including “substantially center”, “substantially equal”, “substantially same”, “substantially orthogonal”, “substantially parallel”, “substantially symmetrical”, “substantially cylindrical”, and the like.

The concepts also include concepts having states in a predetermined range (e.g., ±10% range) with respect to, for example, “exactly center”, “exactly equal”, “exactly same”, “exactly orthogonal”, “exactly parallel”, “exactly symmetrical”, and “exactly cylindrical”.

Therefore, even when the words such as “substantially” and “approximately” are not added, the concepts may include those that are expressed by adding “substantially”, “approximately”, and the like. Conversely, states expressed by adding “substantially”, “approximately”, and the like, do not necessarily exclude their exact states.

In the present disclosure, expressions using the term “than” such as “greater than A” and “less than A” are expressions that comprehensively include concepts that include the case of being equal to A and concepts that do not include the case of being equal to A. For example, “greater than A” is not limited to the case where it does not include “equal to A”; however, it also includes “equal to or greater than A”. Further, “less than A” is not limited to “less than A”; it also includes “equal to or less than A”.

Upon the implementation of the present technology, specific settings and other settings may be suitably adopted from the concepts that are included in “greater than A” and “less than A” to achieve the effects described above.

Among the characteristic portions according to the present technology described above, at least two of the characteristic portions can also be combined. In other words, the various characteristic portions described in each embodiment may be optionally combined regardless of the embodiments. Further, the various effects described above are merely illustrative and not restrictive, and other effects may be exerted.

### REFERENCE SIGNS LIST

F foil
FT foil trap
1, 201 chamber main body
15 connection chamber
16, 90 output port
17 opening
30, 50, 60, 70, 80, 230, 230a, 230b, 230c debris trap unit
31, 51, 61, 231 detachable member
32, 52, 62, 232 rotation shaft
33, 53, 63, 233 rotation drive portion
34 guide mechanism
36, 56, 66, 236 rotary foil trap
54 reinforcement member
55 reinforcement portion
67, 245 fixed foil trap
69, 248 gas introduction pipe
71, 240 foil trap cover
81 heat shielding member
82 detection sensor
92 second opening
100, 200 EUV light source apparatus
250 condensing mirror
262 position adjustment mechanism
270 vibration-isolation mechanism

1. A debris trap unit that is attached to an opening of a chamber main body including an output port for radiation from plasma and the opening different from the output port, the debris trap unit comprising:
a detachable member that covers the opening and is configured to be attachable/detachable to/from the chamber main body; and
at least one foil trap that includes a plurality of foils to capture debris from the plasma, and is connected to the detachable member such that the plurality of foils are disposed on a path of the radiation from the plasma to the output port with the detachable member being attached to the chamber main body.

2. The debris trap unit according to claim 1, wherein
the at least one foil trap includes a rotary foil trap including the plurality of foils and a rotary member that radially supports the plurality of foils, and
the debris trap unit further comprises:
a shaft portion that is connected to the rotary member of the rotary foil trap; and
a rotation drive portion that rotates the shaft portion.

3. The debris trap unit according to claim 2, wherein
the rotation drive portion is connected to an outside of the detachable member,
the shaft portion penetrates the detachable member, and
the rotary member is connected to the shaft portion inside the detachable member.

4. The debris trap unit according to claim 3, further comprising
a reinforcement member that is configured as a separate member from the detachable member and fixes the rotation drive portion to the detachable member.

5. The debris trap unit according to claim 3, wherein
the detachable member includes a reinforcement portion that reinforces rigidity of a portion to which the rotation drive portion is connected.

6. The debris trap unit according to claim 2, wherein
the at least one foil trap includes a fixed foil trap including the plurality of foils and a fixed member that fixes the plurality of foils.

7. The debris trap unit according to claim 6, further comprising
a foil trap cover that is connected to the detachable member, encloses an outer circumferential portion of the rotary foil trap, and collects the debris scattered from the rotary foil trap, wherein
the fixed foil trap is connected to the foil trap cover.

8. The debris trap unit according to claim 6, further comprising
a gas introduction pipe that penetrates the detachable member and introduces a transparent gas to the fixed foil trap, the transparent gas being transparent to the radiation.

9. The debris trap unit according to claim 1, further comprising
a condensing mirror that is connected to the detachable member and condenses the radiation from the plasma, wherein
the at least one foil trap is disposed between the plasma and the condensing mirror.

10. The debris trap unit according to claim 9, further comprising
a position adjustment mechanism that adjusts arrangement of the condensing mirror.

11. The debris trap unit according to claim 9, further comprising
a vibration-isolation mechanism that suppresses vibration transmitted to the chamber main body and/or the condensing mirror.

12. The debris trap unit according to claim 1, further comprising
at least one of a heat shielding member that is connected to the detachable member and is disposed between the plasma and the foil trap, or a detection sensor that is connected to the detachable member and detects a state of the plasma.

13. The debris trap unit according to claim 1, wherein the detachable member includes a guide mechanism that guides an attaching position with respect to the chamber main body.

14. A light source apparatus, comprising:
a plasma generation section that converts a plasma raw material into plasma;
a chamber main body that includes an output port for radiation from plasma generated by the plasma generation section, and an opening different from the output port; and
a debris trap unit that is attached to the opening of the chamber main body, wherein
the debris trap unit includes
a detachable member that covers the opening and is configured to be attachable/detachable to/from the chamber main body, and
at least one foil trap that includes a plurality of foils to capture debris from the plasma, and is connected to the detachable member such that the plurality of foils are disposed on a path of the radiation from the plasma to the output port with the detachable member being attached to the chamber main body.
